(19) United States
(12) Patent Application Publication
(10) Pub. No.: US 2026/0190965 A1
(43) Pub. Date: Jul. 2, 2026

(54) SEMICONDUCTOR DEVICE AND SEMICONDUCTOR PACKAGE INCLUDING THE SAME

(71) Applicant: Samsung Electronics Co., Ltd., Suwon-si (KR)

(72) Inventors: Jisoo Kim, Suwon-si (KR); Dong-Hwan Han, Suwon-si (KR); Hyunjun Bae, Suwon-si (KR); Jahyeong Seo, Suwon-si (KR); KyuTae Jeong, Suwon-si (KR); Hojun Choi, Suwon-si (KR); Jeongeun Her, Suwon-si (KR)

(21) Appl. No.: 19/286,464

(22) Filed: Jul. 31, 2025

(30) Foreign Application Priority Data
Jan. 2, 2025 (KR) 10-2025-0000466

(51) Int. Cl. H01L 23/48; H01L 23/00; H01L 25/065; H10D 80/30; H10D 84/83

(52) U.S. Cl. CPC H10W 20/20; H10D 80/30; H10W 90/00; H10D 84/83; H10W 90/297; H10W 90/722; H10W 90/724

(57) ABSTRACT

A semiconductor device may include a first substrate having a first surface and a second surface, which may be opposite to each other, a logic block provided on the first surface of the first substrate, a power delivery network provided on the second surface of the first substrate, the power delivery network including back-side interconnection lines connected to the logic block, a second substrate provided on the logic block to face the first surface of the first substrate, a redistribution substrate disposed between the first substrate and the second substrate, a first upper penetration structure provided to penetrate the second substrate and connected to the redistribution substrate, and a lower penetration structure connecting the redistribution substrate to a lower chip pad, which is provided on the second surface of the first substrate.

### CROSS-REFERENCE TO RELATED APPLICATION

This patent application claims priority under 35 U.S.C. § 119 to Korean Patent Application No. 10-2025-0000466, filed on Jan. 2, 2025, in the Korean Intellectual Property Office, the entire contents of which are hereby incorporated by reference.

### BACKGROUND

A semiconductor device includes an integrated circuit including metal-oxide-semiconductor field-effect transistors (MOS-FETs). To meet an increasing demand for the semiconductor device with a small pattern size and a reduced design rule, the MOS-FETs are being scaled down. The scale-down of the MOS-FETs may lead to deterioration in operation characteristics of the semiconductor device. Thus, a variety of studies are being conducted to overcome technical limitations associated with the scale-down of the semiconductor device and to realize high performance semiconductor devices.

### SUMMARY

With the active development of three-dimensional (3D) semiconductor packages that integrate a plurality of semiconductor chips into a single semiconductor package, challenges may exist for arrangements of vertically-connected chips and devices. Some implementations according to this disclosure provide processes and device configurations for forming a vertical electrical connection structure penetrating a substrate or die and for ensuring the electrical and mechanical reliability of the connection structure.

Some implementations of the present disclosure provide semiconductor devices, which includes an electrical conduction structure electrically connecting top and bottom ends thereof to each other, thereby improving space availability and the heat-dissipation performance, and semiconductor packages including the same.

In some implementations, a semiconductor device may include a first substrate having a first surface and a second surface, which may be opposite to each other, a logic block provided on the first surface of the first substrate, a power delivery network provided on the second surface of the first substrate, the power delivery network including back-side interconnection lines connected to the logic block, a second substrate provided on the logic block to face the first surface of the first substrate, a redistribution substrate disposed between the first substrate and the second substrate, a first upper penetration structure provided to penetrate the second substrate and connected to the redistribution substrate, and a lower penetration structure connecting the redistribution substrate to a lower chip pad, which is provided on the second surface of the first substrate.

In some implementations, a semiconductor device may include a first substrate having a first surface and a second surface, which are opposite to each other, a logic block provided on the first surface of the first substrate, a power delivery network provided on the second surface of the first substrate, the power delivery network including back-side interconnection lines connected to the logic block, a second substrate provided on the logic block to face the first surface of the first substrate, a first upper penetration structure penetrating the second substrate, a second upper penetration structure provided to penetrate the second substrate and horizontally spaced apart from the first upper penetration structure, a lower penetration structure connecting the first upper penetration structure to a lower chip pad, which is provided on the second surface of the first substrate, and a redistribution substrate connected to the first and second upper penetration structures, on the second substrate. The second upper penetration structure may be connected to the logic block.

In some implementations, a semiconductor package may include a base redistribution substrate, a first semiconductor chip on the base redistribution substrate, and second and third semiconductor chips disposed on the first semiconductor chip and horizontally spaced apart from each other. The first semiconductor chip may include a first substrate, a logic block provided on a first surface of the first substrate, upper interconnection lines provided on the first surface of the first substrate and connected to the logic block, a power delivery network provided on a second surface of the first substrate, the power delivery network including power lines connected to the logic block, a second substrate provided on the logic block to face the first surface of the first substrate, and a connection structure penetrating the first and second substrates. The connection structure may include a redistribution substrate between the first substrate and the second substrate, a first upper penetration structure provided to penetrate the second substrate and connected to the redistribution substrate, and a lower penetration structure connecting the redistribution substrate to a lower chip pad, which is provided on the second surface of the first substrate.

### BRIEF DESCRIPTION OF THE DRAWINGS

FIG. 1 is a sectional view illustrating an example of a semiconductor package including a semiconductor device.

FIG. 2 is a plan view schematically illustrating an example of a semiconductor device.

FIG. 3 is an enlarged plan view illustrating a portion ‘P1’ of FIG. 2.

FIG. 4 is a sectional view taken along a line A-A′ of FIG. 3.

FIGS. 5A to 5E are sectional views illustrating portions of examples of semiconductor device, corresponding to the view of FIG. 4.

FIG. 6 is a plan view schematically illustrating an example of a logic block provided in a semiconductor device.

FIG. 7 is a plan view illustrating a portion of an example of a semiconductor device.

FIG. 8 is a sectional view taken along a line I-I′ of FIG. 7.

FIGS. 9 and 10 are sectional views illustrating examples of semiconductor packages.

FIGS. 11, 12, and 13A to 13E are diagrams illustrating an example of a method of fabricating a semiconductor device.

FIGS. 14A to 14E are diagrams illustrating an example of a method of fabricating a semiconductor device.

### DETAILED DESCRIPTION

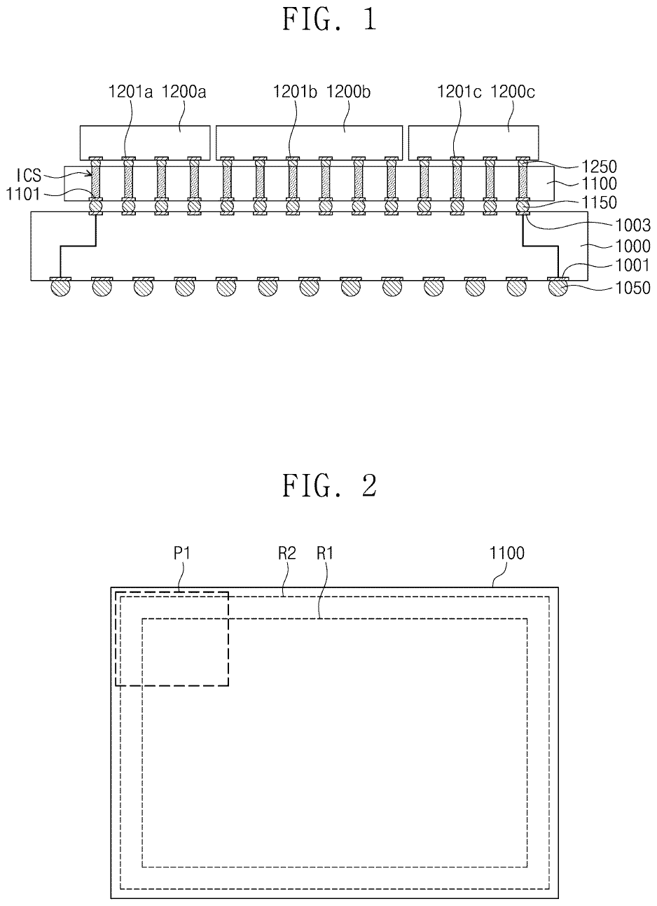

FIG. 1 is a sectional view illustrating an example of a semiconductor package including a semiconductor device.

Referring to FIG. 1, a semiconductor package may include a base redistribution substrate 1000, a first semiconductor device 1100, and second to fourth semiconductor devices 1200a, 1200b, and 1200c.

The base redistribution substrate 1000 may include lower coupling pads 1001, which are disposed on a bottom surface thereof, and upper coupling pads 1003, which are disposed on a top surface thereof. The base redistribution substrate 1000 may include a plurality of base insulating layers and a plurality of redistribution patterns. The redistribution patterns may include conductive line patterns on the base insulating layers and conductive vias vertically penetrating the base insulating layers.

First connection terminals 1050 may be attached to the lower coupling pads 1001 of the base redistribution substrate 1000. Each of the first connection terminals 1050 may be at least one of solder balls, conductive bumps, or conductive pillars. Each of the first connection terminals 1050 may be formed of or include at least one of copper, tin, or lead.

The semiconductor package may exchange signals with an external package or other semiconductor devices through the first connection terminals 1050. For example, power or ground signals for driving the first to fourth semiconductor devices 1100, 1200a, 1200b, and 1200c may be received through at least one of the first connection terminals 1050 of the base redistribution substrate 1000.

The first semiconductor device 1100 may be mounted on the base redistribution substrate 1000. The first semiconductor device 1100 may be a processor or logic chip (e.g., a micro-electromechanical systems (MEMS) device, an optoelectronic device, a central processing unit (CPU), a graphics processing unit (GPU), a mobile application, or a digital signal processor (DSP)).

The first semiconductor device 1100 may include connection structures ICS, which are provided to connect top and bottom surfaces of the first semiconductor device 1100. At least one of the connection structures ICS may be used to provide power signals from the base redistribution substrate 1000 to the second to fourth semiconductor devices 1200a, 1200b, and 1200c. The first semiconductor device 1100 may include lower chip pads 1101 disposed on a bottom surface thereof.

Second connection terminals 1150 may be provided between the upper coupling pads 1003 of the base redistribution substrate 1000 and the lower chip pads 1101 of the first semiconductor device 1100. The second connection terminals 1150 may be solder balls or solder bumps, which are formed of at least one of tin, lead, or copper. In some implementations, the second connection terminals 1150 may be smaller than the first connection terminals 1050.

The second to fourth semiconductor devices 1200a, 1200b, and 1200c may be mounted on the first semiconductor device 1100. Each of the second to fourth semiconductor devices 1200a, 1200b, and 1200c may receive power and signals from the base redistribution substrate 1000 through the first semiconductor device 1100.

The second to fourth semiconductor devices 1200a, 1200b, and 1200c may receive a power voltage from the base redistribution substrate 1000 through at least one of the connection structures ICS in the first semiconductor device 1100 and may receive a ground voltage from the base redistribution substrate 1000 through at least one of the connection structures ICS. In addition, the second to fourth semiconductor devices 1200a, 1200b, and 1200c may exchange signals with the first semiconductor device 1100 through at least one of the connection structures ICS in the first semiconductor device 1100.

As an example, each of the second to fourth semiconductor devices 1200a, 1200b, and 1200c may be a logic chip including at least one processor (e.g., a central processing unit (CPU), an application processor (AP), a graphics processing unit (GPU), a neural processing unit (NPU), a tensor processing unit (TPU), a vision processing unit (VPU), an image signal processor (ISP), and/or a digital signal processor (DSP)). As another example, each of the second to fourth semiconductor devices 1200a, 1200b, and 1200c may be a single chip or a chip stack which includes a memory cell array, a column decoder, a row decoder, a sense amplifier, a write driver, and an input/output buffer, e.g., may include a memory chip.

The first semiconductor device 1100 and the second to fourth semiconductor devices 1200a, 1200b, and 1200c may be connected to each other through third connection terminals 1250. The third connection terminals 1250 may electrically connect the connection structures ICS of the first semiconductor device 1100 to lower chip pads 1201a, 1201b, and 1201c of the second to fourth semiconductor devices 1200a, 1200b, and 1200c. The third connection terminals 1250 may be a solder ball or a solder bump that is formed of tin, lead, or copper. In some implementations, the third connection terminals 1250 may be smaller than the second connection terminals 1150.

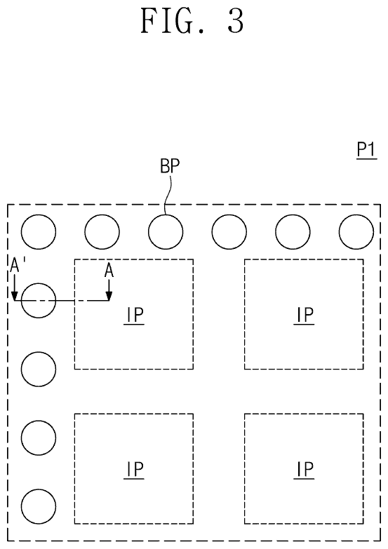

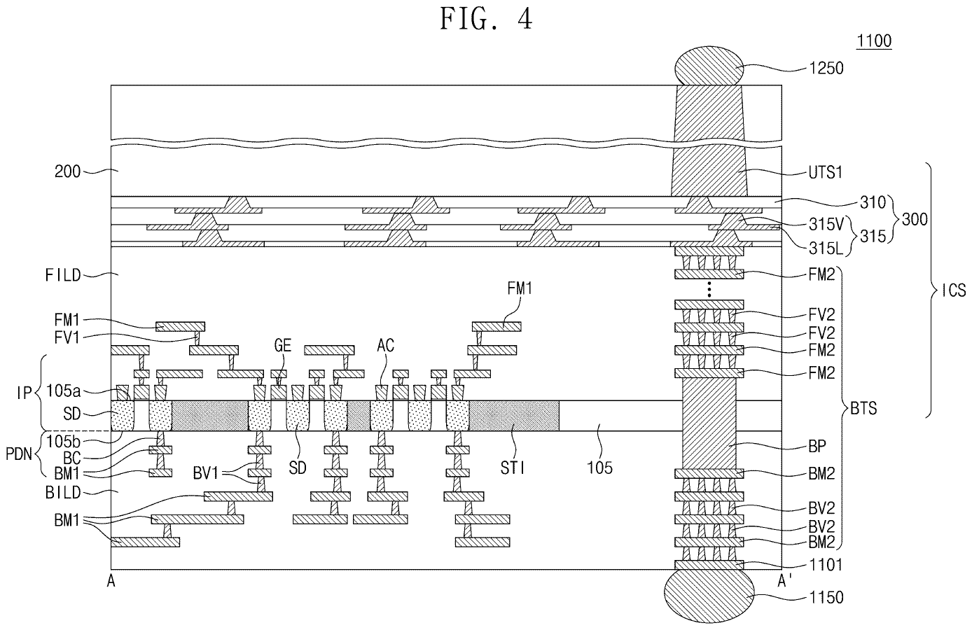

FIG. 2 is a plan view schematically illustrating an example of a semiconductor device, e.g., having characteristics matching or similar to those described in reference to FIG. 1. FIG. 3 is an enlarged plan view illustrating a portion ‘P1’ of FIG. 2. FIG. 4 is a sectional view taken along a line A-A′ of FIG. 3.

Referring to FIGS. 2 and 3, the first semiconductor device 1100 may include a center region R1 and an edge region R2 around the center region R1. Logic blocks IP may be disposed in the center region R1 of the first semiconductor device 1100. The connection structures ICS may be disposed in the edge region R2 of the first semiconductor device 1100.

The logic blocks IP may be arranged in a matrix or array shape. The logic blocks IP may be referred to as functional blocks, hard macros, or intellectual property (IP) blocks. The logic blocks IP may be configured to have a layout and an interconnection structure, which are used to perform the desired electrical function, and may refer to reusable blocks. For example, the logic blocks IP may include macro blocks for data processing and/or calculation operations and memory blocks for storing data. The logic blocks IP may include a plurality of standard cells or a plurality of logic cells. The standard cell may mean a logic device (e.g., AND, OR, XOR, XNOR, inverter, and so forth), which is configured to execute a specific function. For example, the standard cells may include transistors, which constitute the logic device, and interconnection lines, which are used to connect the transistors to each other.

Referring to FIGS. 3 and 4, the first semiconductor device 1100 may include a first substrate 105, the logic blocks IP, a power delivery network (or power distribution network) PDN, a second substrate 200, and the connection structures ICS vertically penetrating the first semiconductor device 1100.

The first substrate 105 may have a first surface 105a and a second surface 105b, which are opposite to each other. The first substrate 105 may include a silicon-based insulating layer. In some implementations, the first substrate 105 may be a semiconductor substrate or an insulating substrate. As an example, the first substrate 105 may include a silicon substrate, and as another example, the first substrate 105 may include a silicon oxide layer, a silicon nitride layer, or a silicon oxynitride layer.

A device isolation layer STI may be disposed in the first substrate 105 to define active regions. The device isolation layer STI may be formed of or include an insulating material (e.g., silicon oxide).

The logic blocks IP may be integrated on the first surface 105a of the first substrate 105. The logic blocks IP may be an AND circuit, an OR circuit, a NOR circuit, an inverter circuit, or a latch circuit. In addition, the logic blocks IP may include field effect transistors, a resistance device, and/or the like.

In some implementations, the logic blocks IP may include gate electrodes GE, which are disposed on the first surface 105a of the first substrate 105, and source/drain patterns SD, which are disposed in portions of the first substrate 105 at both sides of the gate electrodes GE. Active contacts AC may be electrically connected to the source/drain patterns SD.

Upper interconnection lines FM1 may be provided on the first surface 105a of the first substrate 105 and may be connected to the logic blocks IP. The upper interconnection lines FM1 may be electrically connected to the gate electrodes GE and the active contacts AC through contact plugs. The upper interconnection lines FM1 may include a plurality of metal lines, which are stacked with a front-side interlayer insulating layer FILD interposed therebetween, and the upper interconnection lines FM1 at different levels may be electrically connected to each other through upper vias FV1. The upper interconnection lines FM1 may include clock lines, which are used to deliver clock signals, and signal lines, which are used to deliver general signals.

The front-side interlayer insulating layer FILD may be disposed on the first surface 105a of the first substrate 105. The front-side interlayer insulating layer FILD on the first surface 105a may cover the logic blocks IP, the upper interconnection lines FM1, and the upper vias FV1. The front-side interlayer insulating layer FILD may have a multi-layered insulating structure, which includes at least one of silicon oxide, silicon nitride, or silicon oxynitride.

The second substrate 200 may be disposed on the first surface 105a of the first substrate 105. The second substrate 200 may be disposed on the logic blocks IP and the front-side interlayer insulating layer FILD, and the second substrate 200 may have a bottom surface that is opposite to the first surface 105a of the first substrate 105. The second substrate 200 may have a relatively high thermal conductivity, compared to the front-side interlayer insulating layer FILD. As an example, the second substrate 200 may be a semiconductor substrate (e.g., a silicon substrate) and may further include silicon carbide. As another example, the second substrate 200 may be formed of or include at least one of diamond, aluminum nitride (AlN), or boron nitride (BN).

The power delivery network PDN may be provided on the second surface 105b of the first substrate 105. The power delivery network PDN may include a plurality of back-side interconnection lines BM1, which are stacked with a back-side interlayer insulating layer BILD interposed therebetween. The back-side interconnection lines BM1 may include power lines, which are used to deliver a power voltage or a ground voltage. The back-side interconnection lines BM1 at different levels may be electrically connected to each other through back-side vias BV1. The back-side interlayer insulating layer BILD between the back-side interconnection lines BM1 may have a multi-layered insulating structure, which includes at least one of silicon oxide, silicon nitride, or silicon oxynitride.

The power lines of the back-side interconnection lines BM1 may be electrically connected to the source/drain patterns SD through back-side contacts BC penetrating the first substrate 105. The back-side contacts BC may have a diameter ranging from a few nanometers to a few micrometers. The back-side contacts BC may have a vertical length ranging from about several tens of nanometers to several micrometers. An insulating layer may be interposed between side surfaces of the back-side contacts BC and the first substrate 105. The back-side interconnection lines BM1, the back-side contacts BC, and the back-side vias BV1 may be formed of or include at least one suitable metallic material (e.g., W, WN, WC, Ti, TiN, Ta, TaN, Ru, Co, Mn, WN, Ni, and/or NiB).

Each of the connection structures ICS may include a lower penetration structure BTS, a first upper penetration structure UTS1 penetrating the second substrate 200, and a redistribution substrate 300 between the first substrate 105 and the second substrate 200. The connection structures ICS may connect the base redistribution substrate 1000 (e.g., of FIG. 1) to the second to fourth semiconductor devices 1200a, 1200b, and 1200c (e.g., of FIG. 1). The connection structures ICS may be used to deliver power or ground voltages from the base redistribution substrate 1000 to the second to fourth semiconductor devices 1200a, 1200b, and 1200c (e.g., of FIG. 1).

The lower penetration structure BTS may be vertically extended to penetrate the first substrate 105. The lower penetration structure BTS may include a penetration conductive pattern BP penetrating the first substrate 105, upper conductive patterns FM2, and lower conductive patterns BM2. The lower penetration structure BTS may electrically connect the redistribution substrate 300 to the lower chip pad 1101. The lowermost one of the lower conductive patterns BM2 may be connected to the lower chip pad 1101 through lower conductive vias BV2. The second connection terminal 1150 may be attached to a bottom surface of the lower chip pad 1101.

The penetration conductive pattern BP may be horizontally spaced apart from the logic block IP and may be provided to penetrate the first substrate 105. The penetration conductive pattern BP may have a vertical length, which is smaller than the first upper penetration structure UTS1, and a diameter, which is smaller than the first upper penetration structure UTS1. The penetration conductive pattern BP may have a diameter (or a horizontal width) ranging from about several tens of nanometers to several tens of micrometers. A top surface of the penetration conductive pattern BP may be higher than the first surface 105a of the first substrate 105. The penetration conductive pattern BP may be formed of or include at least one metallic material (e.g., W, WN, WC, Ti, TiN, Ta, TaN, Ru, Co, Mn, WN, Ni, and/or NiB).

The upper conductive patterns FM2 may be vertically stacked on the top surface of the penetration conductive pattern BP. For example, the upper conductive patterns FM2 may be vertically overlapped with the penetration conductive pattern BP. The upper conductive patterns FM2 may be disposed on the first surface 105a of the first substrate 105. The upper conductive patterns FM2 may have a rectangular, square, or polygonal shape, when viewed in a plan view. However, the shape of the upper conductive patterns FM2 is not limited to these examples and may be variously changed in consideration of the resistance of each pattern. The lowermost one of the upper conductive patterns FM2 may cover the top surface of the penetration conductive pattern BP. The number and levels of the upper conductive patterns FM2 stacked may be variously changed.

At least one of the upper conductive patterns FM2 may be placed at substantially the same level as the upper interconnection lines FM1 connected to the logic blocks IP. In some implementations, a top surface of the lowermost one of the upper conductive patterns FM2 may be substantially coplanar with a top surface of at least one of the upper interconnection lines FM1. At least one of the lower conductive patterns BM2 may be located at substantially the same level as the back-side interconnection lines BM1 connected to the logic blocks IP. In some implementations, a bottom surface of the uppermost one of the lower conductive patterns BM2 may be substantially coplanar with a bottom surface of at least one of the back-side interconnection lines BM1.

The lower conductive patterns BM2 may be vertically stacked on a bottom surface of the penetration conductive pattern BP. The lower conductive patterns BM2 may be vertically overlapped with the penetration conductive pattern BP. The penetration conductive pattern BP, the upper conductive patterns FM2, and the lower conductive patterns BM2 may be vertically overlapped with each other. The lower conductive patterns BM2 may be disposed on the second surface 105b of the first substrate 105. The lower conductive patterns BM2 may have a rectangular, square, or polygonal shape, when viewed in a plan view. However, the shape of the lower conductive patterns BM2 is not limited to these examples and may be variously changed in consideration of the resistance of each pattern. In some implementations, the uppermost one of the lower conductive patterns BM2 may cover the bottom surface of the penetration conductive pattern BP. The number and levels of the lower conductive patterns BM2 stacked may be variously changed.

The lower penetration structure BTS may further include upper conductive vias FV2, which are disposed between the upper conductive patterns FM2, and the lower conductive vias BV2, which are disposed between the lower conductive patterns BM2. The upper conductive vias FV2 may be disposed between vertically adjacent ones of the upper conductive patterns FM2 to electrically connect adjacent ones of the upper conductive patterns FM2 to each other. The lower conductive vias BV2 may be disposed between vertically adjacent ones of the lower conductive patterns BM2 to electrically connect adjacent ones of the lower conductive patterns BM2 to each other. Each of the upper conductive patterns FM2, the lower conductive patterns BM2, the upper conductive vias FV2, and the lower conductive vias BV2 may be formed of or include at least one metallic material (e.g., W, WN, WC, Ti, TiN, Ta, TaN, Ru, Co, Mn, WN, Ni, and/or NiB).

The first upper penetration structure UTS1 may be provided to penetrate the second substrate 200. The first upper penetration structure UTS1 may be disposed on the lower penetration structure BTS. As an example, the first upper penetration structure UTS1 may be vertically overlapped with the lower penetration structure BTS, but the arrangement of the first upper penetration structure UTS1 is not limited to this example. The third connection terminal 1250 may be attached to the first upper penetration structure UTS1. The largest width of each of the third connection terminals 1250 may be smaller than the largest width of each of the second connection terminals 1150. The largest width of each of the second and third connection terminals 1150 and 1250 may be a width in a horizontal direction. In some implementations, a chip pad may be additionally disposed between the first upper penetration structure UTS1 and the third connection terminal 1250.

The first upper penetration structure UTS1 may have a diameter (or a horizontal width) ranging from about several tens of nanometers to about several hundreds of micrometers. The first upper penetration structure UTS1 may have a circular or elliptical shape, when viewed in a plan view, but the shape is not limited to this example. For example, the first upper penetration structure UTS1 may have a bar shape extending in a specific direction, when viewed in a plan view. The first upper penetration structure UTS1 may be formed of or include at least one metallic material (e.g., W, WN, WC, Ti, TiN, Ta, TaN, Ru, Co, Mn, WN, Ni, and/or NiB).

The redistribution substrate 300 may be disposed between the first upper penetration structure UTS1 and the lower penetration structure BTS. The redistribution substrate 300 may include insulating layers 310 and redistribution patterns 315. The insulating layers 310 may be disposed between the front-side interlayer insulating layer FILD and the second substrate 200. In some implementations, the insulating layers 310 may be formed of or include an organic material (e.g., a photoimageable dielectric (PID) material). The PID material may be at least one of polymers. The PID material may include at least one of photoimageable polyimide, polybenzoxazole, phenol-based polymers, or benzocyclobutene-based polymers. FIG. 4 illustrates an example, in which the insulating layers 310 have an interfacial surface therebetween, but the layer configuration is not limited to this example. In some implementations, there may be no observable interface between adjacent ones of the insulating layers 310.

The redistribution patterns 315 may be disposed in the insulating layers 310. Each of the redistribution patterns 315 may be provided to penetrate at least a portion of the insulating layers 310. Each of the redistribution patterns 315 may include a line portion 315L and a via portion 315V. Each of the line portions 315L may be extended in a direction parallel to the first surface 105a of the first substrate 105. Each of the via portions 315V may be connected to the line portion 315L and may mean a portion protruding upward from the line portion 315L. Each of the via portions 315V may have an increasing width as a distance to the first surface 105a of the first substrate 105 decreases. The redistribution patterns 315 may be formed of or include at least one metallic material (e.g., copper (Cu)). Seed patterns may be disposed on bottom surfaces of the redistribution patterns 315. For example, each of the seed patterns may cover bottom and side surfaces of the via portion 315V of a corresponding one of the redistribution patterns 315 and a bottom surface of the line portion 315L. The seed patterns may include a material different from the redistribution patterns 315. The seed patterns may be formed of or include at least one of, for example, copper (Cu), titanium (Ti), or alloys thereof. In some implementations, the redistribution patterns 315 may further include a barrier layer preventing a material in the redistribution patterns 315 from being diffused into a neighboring element. The barrier layer may be formed of or include titanium nitride (TiN) or tantalum nitride (TaN).

The first upper penetration structure UTS1 may be electrically connected to the lower penetration structure BTS through the redistribution substrate 300. For example, the first upper penetration structure UTS1 may be in contact with a top surface of the uppermost corresponding one of the redistribution patterns 315, and the lower penetration structure BTS may be in contact with a bottom surface of the lowermost corresponding one of the redistribution patterns 315.

Accordingly, the first upper penetration structure UTS1, the redistribution substrate 300, and the lower penetration structure BTS may be connected to each other to form a connection structure ICS, which is used as an electric conduction path electrically connecting top and bottom portions of the first semiconductor device 1100.

As an example, in the case where a penetration structure is provided as a single object penetrating the first and second substrates 105 and 200 (additionally, the front-side interlayer insulating layer FILD and the back-side interlayer insulating layer BILD), it may be necessary to deeply form a recess for the penetration structure, and this may increase the process difficulty in the fabrication process. Furthermore, the recess may be generally formed to have a high aspect ratio, and in this case, the penetration structure may be formed to have a large horizontal width. Thus, to minimize the electric interference between the penetration structure and the logic block IP, it may be necessary to separate the penetration structure from the logic block IP by a distance larger than a minimum distance constraint, and this may lower the area efficiency or integration efficiency of the semiconductor chip.

However, according to some implementations of the present disclosure, since the first upper penetration structure UTS1 and the lower penetration structure BTS are separately or respectively formed, it may be possible to reduce a process difficulty in etching steps, which are performed during the process of forming the penetration structures. In addition, the lower penetration structure BTS may have a horizontal width, which is smaller than that of the penetration structure in the previous example, and thus, it may be possible to increase the area efficiency or integration efficiency of the semiconductor chip.

Furthermore, according to some implementations of the present disclosure, the redistribution substrate 300 may be configured to effectively transfer electrical signals and/or power, which are transferred from the upper interconnection lines FM1 and the lower penetration structures BTS, to the second to fourth semiconductor devices 1200a, 1200b, and 1200c (e.g., of FIG. 1) on the first semiconductor device 1100. Thus, the second to fourth semiconductor devices 1200a, 1200b, and 1200c (e.g., of FIG. 1), which are horizontally spaced apart from each other, may be provided on the first semiconductor device 1100 and may be operated respectively or independently.

In addition, according to some implementations of the present disclosure, heat, which is generated when the first semiconductor device 1100 is operated, may be transferred to the second substrate 200 with high thermal conductivity and may be exhausted to the outside through the side surfaces of the second substrate 200. In this case, it may be possible to improve the heat-dissipation performance of the first semiconductor device 1100 and to at least partially prevent the performance of the first semiconductor device 1100 from being deteriorated.

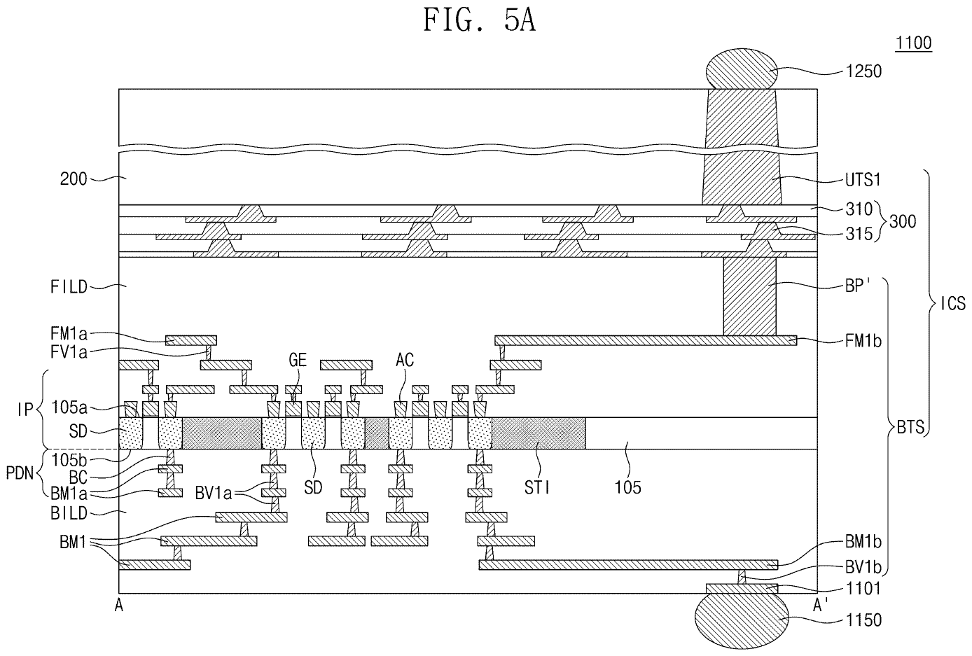

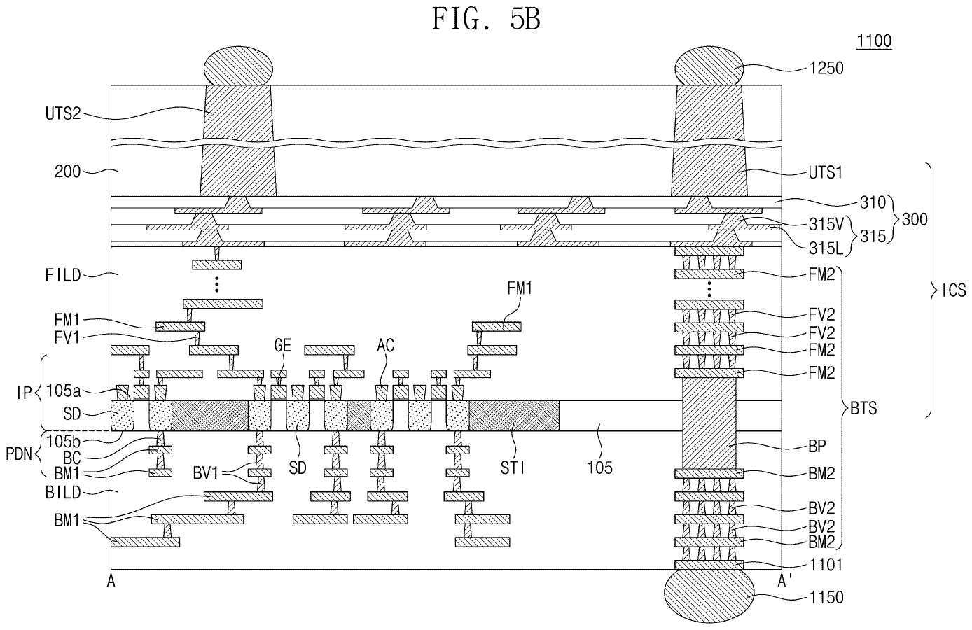

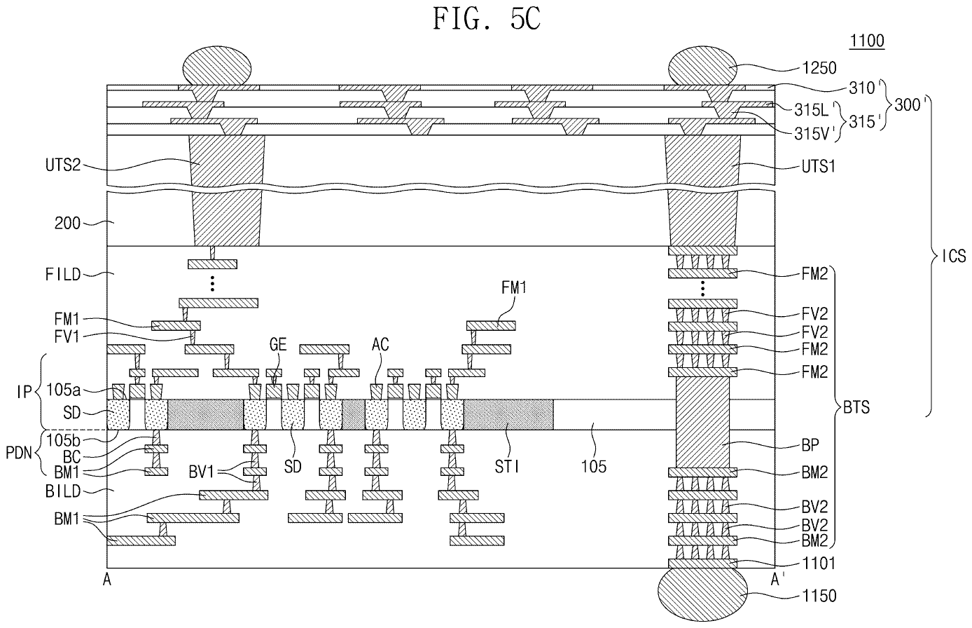

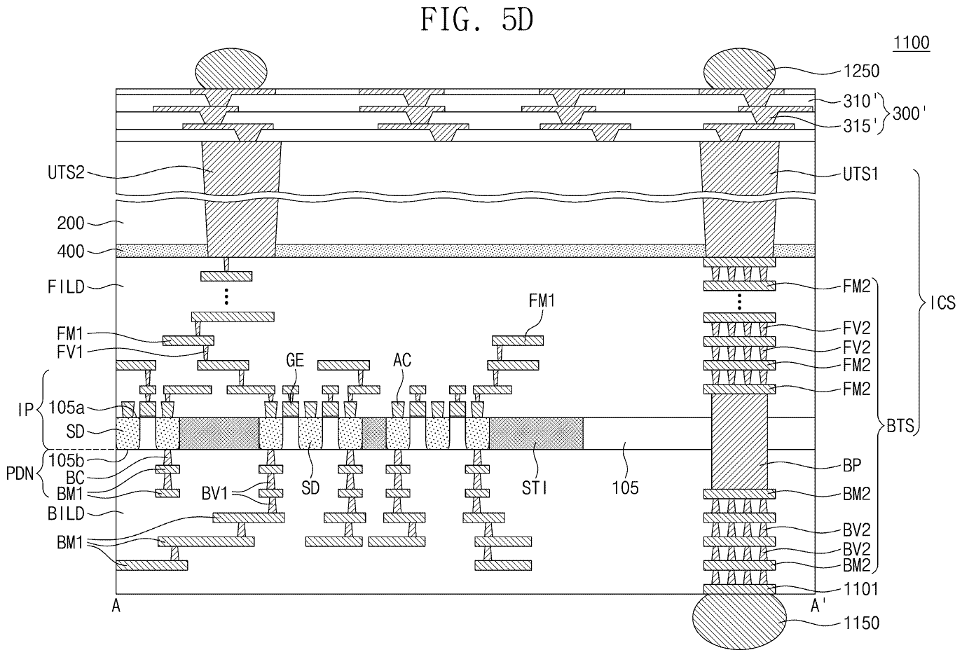

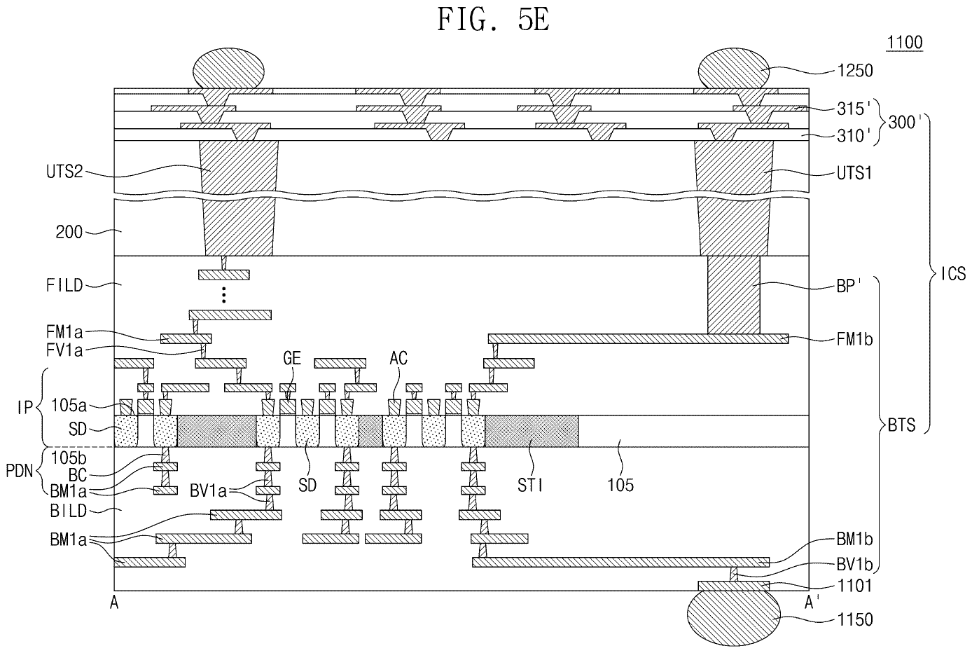

FIGS. 5A to 5E are sectional views illustrating examples of a portion of a semiconductor device, with a view corresponding to FIG. 4. In the following description, a previously described element may be identified by the same reference number without repeating an overlapping description thereof, for the sake of brevity.

Referring to FIG. 5A, the lower penetration structure BTS may be provided to electrically connect the redistribution substrate 300 to the lower chip pad 1101. The lower penetration structure BTS may include a penetration conductive pattern BP′, one or more upper interconnection lines FM1a and FM1b (e.g., FM1b), and one or more back-side interconnection lines BM1a and BM1b (e.g., BM1b).

The penetration conductive pattern BP′ may be provided in the front-side interlayer insulating layer FILD and may be vertically spaced apart from the first substrate 105. For example, the penetration conductive pattern BP′ may be located at a level higher than the first substrate 105. The penetration conductive pattern BP′ may be electrically connected to a corresponding one of the redistribution patterns 315. The penetration conductive pattern BP′ may be in contact with the lowermost one of the redistribution patterns 315, but the arrangement is not limited to this example. In some implementations, metal lines may be disposed between the penetration conductive pattern BP′ and the corresponding redistribution pattern 315.

One or more (e.g., the second upper interconnection lines FM1b) of the upper interconnection lines FM1a and FM1b connected to the logic block IP may electrically connect the penetration conductive pattern BP′ to the source/drain pattern SD. In some implementations, the uppermost one of the second upper interconnection lines FM1b may be horizontally extended to be in contact with a bottom surface of the penetration conductive pattern BP′.

One or more (e.g., the second back-side interconnection lines BM1b) of the back-side interconnection lines BM1a and BM1b connected to the logic block IP may electrically connect the lower chip pad 1101 to the source/drain pattern SD. The lowermost one of the second back-side interconnection lines BM1b may be horizontally extended and may be vertically overlapped with the lower chip pad 1101. The lowermost one of the second back-side interconnection lines BM1b may be electrically connected to the lower chip pad 1101 through a back-side via BV1b.

Referring to FIG. 5B, the first semiconductor device 1100 may include a second upper penetration structure UTS2, which is horizontally spaced apart from the first upper penetration structure UTS1. The second upper penetration structure UTS2 may be provided to penetrate the second substrate 200 and may be electrically connected to the redistribution substrate 300. The second upper penetration structure UTS2 may be in contact with a top surface of the uppermost corresponding one of the redistribution patterns 315.

The redistribution patterns 315 corresponding to the second upper penetration structure UTS2 may be connected to the upper interconnection lines FM1. The second upper penetration structure UTS2 may be connected to the logic block IP through the upper interconnection lines FM1. The second upper penetration structure UTS2, the redistribution patterns 315, and the upper interconnection lines FM1 may be used to transfer electrical signals and/or a power signal, which are transferred from the logic block IP, to the second to fourth semiconductor devices 1200a, 1200b, and 1200c (e.g., of FIG. 1) on the first semiconductor device 1100.

Referring to FIG. 5C, a redistribution substrate 300′ may be disposed on the second substrate 200. The third connection terminal 1250 may be disposed on the redistribution substrate 300′. The redistribution substrate 300′ may include insulating layers 310′ and redistribution patterns 315′. The insulating layers 310′ may be disposed on the second substrate 200. In some implementations, the insulating layers 310′ may be formed of or include an organic material (e.g., a photoimageable dielectric (PID) material).

The redistribution patterns 315′ may be disposed in the insulating layers 310′. Each of the redistribution patterns 315′ may be provided to penetrate at least a portion of the insulating layers 310′. Each of the redistribution patterns 315 may include a line portion 315L′ and a via portion 315V′. Each of the line portions 315L′ may be extended in a direction parallel to the first surface 105a of the first substrate 105. Each of the via portions 315V′ may be connected to the line portion 315L′ and may mean a portion protruding upward from a bottom surface of the line portion 315L′. A width of each of the via portions 315V′ may decrease as a distance to the first surface 105a of the first substrate 105 decreases. The redistribution patterns 315′ may be formed of or include at least one metallic material (e.g., copper (Cu)).

The first and second upper penetration structures UTS1 and UTS2 may be provided to penetrate the second substrate 200. The first and second upper penetration structures UTS1 and UTS2 may be horizontally spaced apart from each other. Each of the first and second upper penetration structures UTS1 and UTS2 may be electrically connected to a corresponding one of the redistribution patterns 315′. A width of each of the first and second upper penetration structures UTS1 and UTS2 may decrease as a distance to the first surface 105a of the first substrate 105 decreases.

The first upper penetration structure UTS1 may be electrically connected to the lower penetration structure BTS. The lower penetration structure BTS may be substantially the same as the lower penetration structure BTS described with reference to FIG. 4.

The second upper penetration structure UTS2 may be connected to the upper interconnection lines FM1. The second upper penetration structure UTS2 may be connected to the logic block IP through the upper interconnection lines FM1. The redistribution patterns 315′, the second upper penetration structure UTS2, and the upper interconnection lines FM1 may be used to transfer electrical signals and/or power, which are transferred from the logic block IP, to the second to fourth semiconductor devices 1200a, 1200b, and 1200c (e.g., of FIG. 1) on the first semiconductor device 1100.

Referring to FIG. 5D, a heat-dissipation pattern 400 may be disposed between the second substrate 200 and the front-side interlayer insulating layer FILD. For example, the heat-dissipation pattern 400 may be disposed on a bottom surface of the second substrate 200. The heat-dissipation pattern 400 may have a relatively high thermal conductivity, compared to the front-side interlayer insulating layer FILD. Heat, which is generated when the first semiconductor device 1100 is operated, may be transferred to the second substrate 200 with high thermal conductivity as well as to the heat-dissipation pattern 400 and may be exhausted to the outside through the side surfaces of the second substrate 200 and the heat-dissipation pattern 400. In some implementations, the heat-dissipation pattern 400 may be formed of or include at least one of aluminum nitride (AlN), diamond, diamond-like carbon (DLC), or graphene.

Each of the first and second upper penetration structures UTS1 and UTS2 may be provided to penetrate the heat-dissipation pattern 400. The first upper penetration structure UTS1 may be provided to penetrate the heat-dissipation pattern 400 and may be connected to the upper interconnection lines FM1. The second upper penetration structure UTS2 may be provided to penetrate the heat-dissipation pattern 400 and may be connected to the lower penetration structure BTS.

Referring to FIG. 5E, the lower penetration structure BTS may be provided to connect the first upper penetration structure UTS1 to the lower chip pad 1101. The lower penetration structure BTS may include the penetration conductive pattern BP′, one or more of the upper interconnection lines FM1a and FM1b (e.g., FM1b), and one or more of the back-side interconnection lines BM1a and BM1b (e.g., BM1b).

The penetration conductive pattern BP′ may be provided in the front-side interlayer insulating layer FILD and may be vertically spaced apart from the first substrate 105. For example, the penetration conductive pattern BP′ may be located at a level higher than the first substrate 105. As an example, the penetration conductive pattern BP′ may be in contact with the first upper penetration structure UTS1. As another example, metal lines may be disposed between the penetration conductive pattern BP′ and the first upper penetration structure UTS1.

One or more (e.g., the second upper interconnection lines FM1b) of the upper interconnection lines FM1a and FM1b connected to the logic block IP may electrically connect the penetration conductive pattern BP′ to the source/drain pattern SD. In some implementations, the uppermost one of the second upper interconnection lines FM1b may be horizontally extended to be in contact with the bottom surface of the penetration conductive pattern BP′.

At least one of the back-side interconnection lines BM1a and BM1b connected to the logic block IP (e.g., the second back-side interconnection line BM1b) may electrically connect the lower chip pad 1101 to the source/drain pattern SD. The lowermost one of the second back-side interconnection lines BM1b may be horizontally extended and may be vertically overlapped with the lower chip pad 1101. The lowermost one of the second back-side interconnection lines BM1b may be electrically connected to the lower chip pad 1101 through the back-side via BV1b.

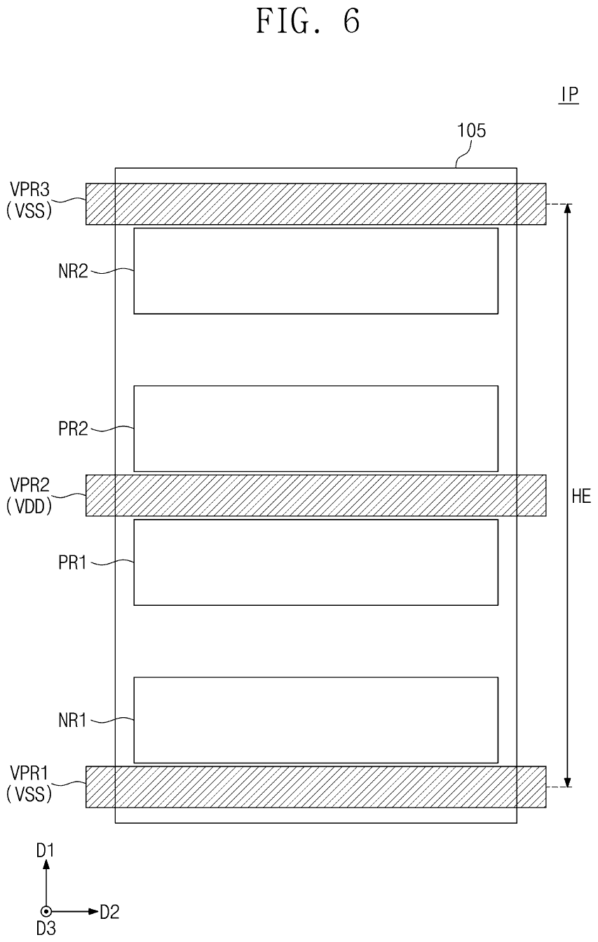

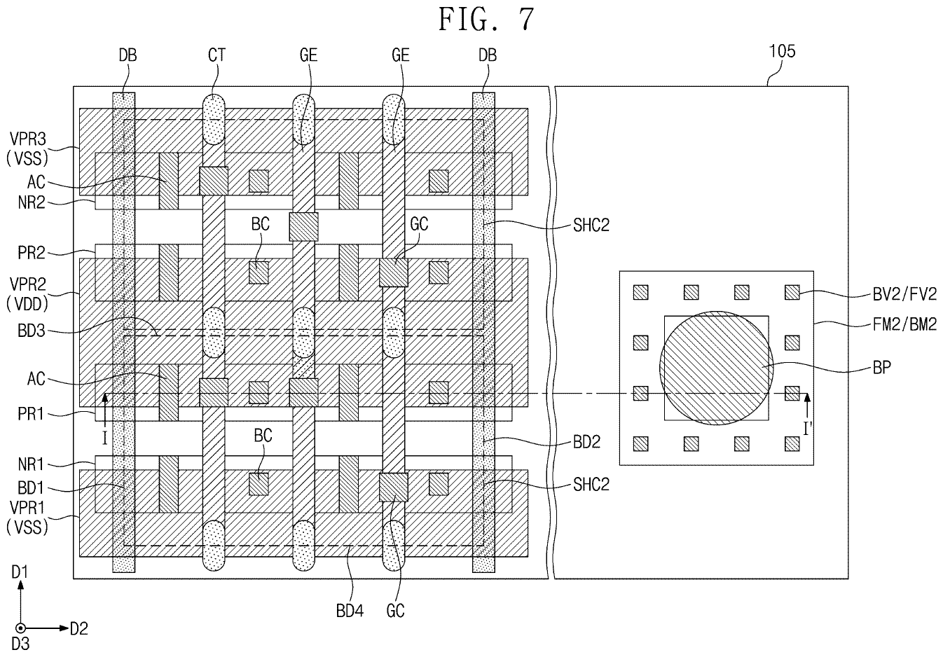

FIG. 6 is a plan view schematically illustrating an example of a logic block, which may be provided as a part of a semiconductor device.

Referring to FIG. 6, a first lower power line VPR1, a second lower power line VPR2, and a third lower power line VPR3 may be provided on the first substrate 105. The second lower power line VPR2 may be disposed between the first lower power line VPR1 and the third lower power line VPR3.

The first substrate 105 of the logic block IP may include a first PMOSFET region PR1, a second PMOSFET region PR2, a first NMOSFET region NR1, and a second NMOSFET region NR2.

The first NMOSFET region NR1 may be adjacent to the first lower power line VPR1. The second NMOSFET region NR2 may be adjacent to the third lower power line VPR3. The first and second PMOSFET regions PR1 and PR2 may be adjacent to the second lower power line VPR2. When viewed in a plan view, the second lower power line VPR2 may be disposed between the first and second PMOSFET regions PR1 and PR2.

A length of the logic block IP in a first direction D1 may be defined as a first spacing HE. The first spacing HE may be about 2 times a distance (e.g., pitch) between the first lower power line VPR1 and the second lower power line VPR2. The first and second PMOSFET regions PR1 and PR2 of the logic block IP may be combined to serve as a single PMOSFET region..

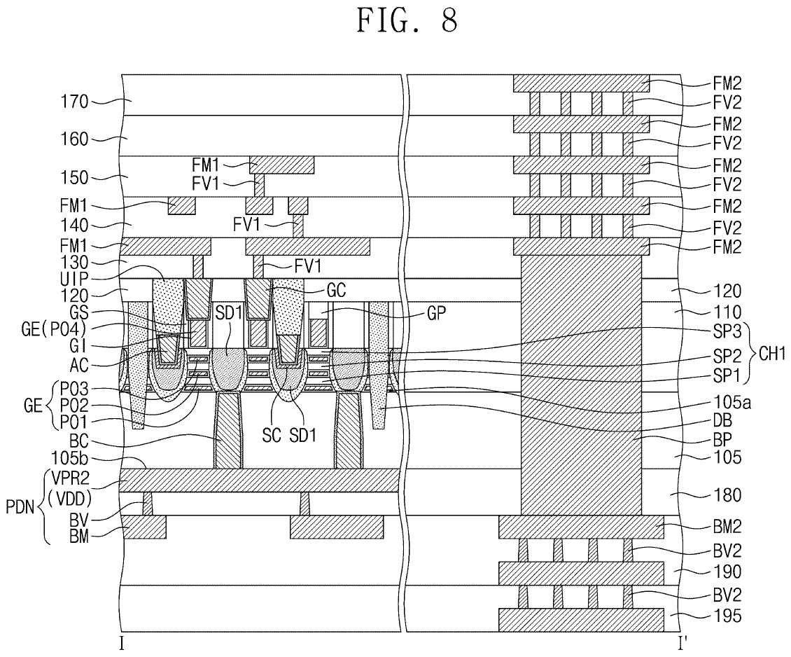

FIG. 7 is a plan view illustrating a portion of an example of a semiconductor device, e.g., a semiconductor device having the logic block of FIG. 6. FIG. 8 is a sectional view taken along a line I-I′ of FIG. 7.

Referring to FIGS. 6 to 8, logic transistors constituting the logic block IP may be disposed on the first substrate 105. The first substrate 105 may include a silicon-based insulating layer. In some implementations, the first substrate 105 may be an insulating substrate. For example, the first substrate 105 may include a silicon oxide layer, a silicon nitride layer, or a silicon oxynitride layer.

The first substrate 105 may include the first PMOSFET region PR1, the second PMOSFET region PR2, the first NMOSFET region NR1, and the second NMOSFET region NR2. Each of the first PMOSFET region PR1, the second PMOSFET region PR2, the first NMOSFET region NR1, and the second NMOSFET region NR2 may be extended in a second direction D2.

First and second insulating patterns (or active patterns) extending in the second direction D2 may be defined in an upper portion of the first substrate 105. Each of the first and second insulating patterns may be a vertically-protruding portion of the substrate 105. The first insulating pattern may be provided on each of the first and second PMOSFET regions PR1 and PR2. The second insulating pattern may be provided on each of the first and second NMOSFET regions NR1 and NR2.

First channel patterns CH1 may be respectively provided on the first and second PMOSFET regions PR1 and PR2, and second channel patterns may be respectively provided on the first and second NMOSFET regions NR1 and NR2.

Each of the first channel pattern CH1 and the second channel pattern may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (i.e., a third direction D3).

Each of the first to third semiconductor patterns SP1, SP2, and SP3 may be formed of or include silicon (Si), germanium (Ge), or silicon germanium (SiGe). For example, each of the first to third semiconductor patterns SP1, SP2, and SP3 may be formed of or include crystalline silicon. In some implementations, each of the first to third semiconductor patterns SP1, SP2, and SP3 may be a nanosheet.

First source/drain patterns SD1 may be provided at both sides of the first channel pattern CH1. The first source/drain patterns SD1 may be impurity regions of a first conductivity type (e.g., p-type). The first channel pattern CH1 may be interposed between each pair of the first source/drain patterns SD1. For example, each pair of the first source/drain patterns SD1 may be connected to each other by the stacked first to third semiconductor patterns SP1, SP2, and SP3.

Second source/drain patterns may be provided at both sides of the second channel patterns provided on the first and second NMOSFET regions NR1 and NR2. The second source/drain patterns may be impurity regions of a second conductivity type (e.g., n-type). The second channel pattern may be interposed between a pair of second source/drain patterns. For example, each pair of the second source/drain patterns may be connected to each other by the stacked first to third semiconductor patterns SP1, SP2, and SP3.

The first source/drain patterns SD1 may be epitaxial patterns formed by a selective epitaxial growth (SEG) process. As an example, a top surface of each of the first source/drain patterns SD1 may be positioned at substantially the same level as a top surface of the third semiconductor pattern SP3. As another example, the top surface of each of the first source/drain patterns SD1 may be higher than the top surface of the third semiconductor pattern SP3. Similarly, the second source/drain patterns may also be epitaxial patterns.

The first source/drain pattern SD1 may further include n-type dopants (e.g., phosphorus, arsenic, or antimony). The first source/drain patterns SD1 may be formed of or include a semiconductor material (e.g., SiGe) whose lattice constant is greater than that of the first channel pattern CH1. In this case, the pair of the first source/drain patterns SD1 may exert a compressive stress on the first channel pattern CH1 therebetween. The second source/drain patterns provided on the first and second NMOSFET regions NR1 and NR2 may be formed of or include the same semiconductor material (e.g., Si) as the second channel pattern.

Each of the second source/drain patterns may include silicon (Si). The second source/drain pattern may further include n-type dopants (e.g., phosphorus, arsenic, or antimony).

The gate electrodes GE may be extended in the first direction D1 to cross the first channel patterns CH1 and the second channel patterns. The gate electrodes GE may be arranged at a first pitch in the second direction D2.

The gate electrode GE may include a first inner electrode PO1 interposed between the first substrate 105 and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

The gate electrode GE may be provided on a top surface, a bottom surface, and opposite side surfaces of each of the first to third semiconductor patterns SP1, SP2, and SP3. For example, the transistor may be a three-dimensional field effect transistor (e.g., MBCFET or GAAFET) in which the gate electrode GE is provided to three-dimensionally surround the channel pattern.

Gate cutting patterns CT may be disposed to be overlapped with the gate electrodes GE, respectively. The gate cutting patterns CT may be formed of or include at least one of insulating materials (e.g., silicon oxide, silicon nitride, or combinations thereof).

The gate electrode GE may include a plurality of portions, which are spaced apart from each other in the first direction D1 by the gate cutting pattern CT. For example, the gate electrode GE extending in the first direction D1 may be divided into a plurality of gate electrodes GE by the gate cutting patterns CT.

A pair of gate spacers GS may be respectively disposed on opposite side surfaces of the outer electrode PO4 of the gate electrode GE. The gate spacers GS may be extended along the gate electrode GE and in the first direction D1. Top surfaces of the gate spacers GS may be higher than a top surface of the gate electrode GE. The top surfaces of the gate spacers GS may be substantially coplanar with a top surface of a first interlayer insulating layer 110, which will be described below. The gate spacers GS may be formed of or include at least one of SiCN, SiCON, or SiN. In some implementations, the gate spacers GS may be a multi-layered structure, which includes at least two different materials selected from SiCN, SiCON, and SiN.

A gate capping pattern GP may be provided on the gate electrode GE. The gate capping pattern GP may be extended along the gate electrode GE and in the first direction D1. The gate capping pattern GP may be formed of or include a material having an etch selectivity with respect to first and second interlayer insulating layers 110 and 120, which will be described below. For example, the gate capping pattern GP may be formed of or include at least one of silicon oxynitride (SiON), silicon carbon nitride (SiCN), silicon carbon oxynitride (SiCON), or silicon nitride (SiN).

A gate insulating layer GI may be interposed between the gate electrode GE and the first channel pattern CH1 and between the gate electrode GE and the second channel pattern. The gate insulating layer GI may cover a top surface, a bottom surface, and opposite side surfaces of each of the first to third semiconductor patterns SP1, SP2, and SP3.

The gate insulating layer GI may include a silicon oxide layer, a silicon oxynitride layer, and/or a high-k dielectric layer. The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The gate electrode GE may include a first metal pattern and a second metal pattern on the first metal pattern. The first metal pattern may be provided on the gate insulating layer GI and may be adjacent to the first to third semiconductor patterns SP1, SP2, and SP3. The first metal pattern may include a work-function metal, which can be used to adjust a threshold voltage of the transistor. By adjusting a thickness and composition of the first metal pattern, it may be possible to realize a transistor having a desired threshold voltage. For example, the first to third inner electrodes PO1, PO2, and PO3 of the gate electrode GE may be composed of the first metal pattern or the work-function metal.

The first metal pattern may include a metal nitride layer. For example, the first metal pattern may include at least one metal, which is selected from the group consisting of titanium (Ti), tantalum (Ta), aluminum (Al), tungsten (W) and molybdenum (Mo), and nitrogen (N). In some implementations, the first metal pattern may further include carbon (C). The first metal pattern may include a plurality of work function metal layers, which are stacked.

The second metal pattern may be formed of or include a metallic material whose resistance is lower than the first metal pattern. For example, the second metal pattern may be formed of or include at least one metallic material, which is selected from the group consisting of tungsten (W), aluminum (Al), titanium (Ti), and tantalum (Ta). For example, the outer electrode PO4 of the gate electrode GE may include the first metal pattern and the second metal pattern on the first metal pattern.

The first interlayer insulating layer 110 may be provided on the first substrate 105. The first interlayer insulating layer 110 may cover the gate spacers GS, the first source/drain patterns SD1, and the second source/drain patterns. The first interlayer insulating layer 110 may have a top surface that is substantially coplanar with the top surface of the gate capping pattern GP and the top surface of the gate spacer GS. A second interlayer insulating layer 120 may be formed on the first interlayer insulating layer 110 to cover the gate capping pattern GP. Third, fourth, fifth, sixth, and seventh interlayer insulating layers 130, 140, 150, 160, and 170 may be provided on the second interlayer insulating layer 120. The upper interconnection lines FM1 and the upper vias FV1, which are connected to the logic block IP, may be disposed in the first to seventh interlayer insulating layers 110 to 170. The number of the interlayer insulating layers stacked and the number of the upper interconnection lines FM1 connected to the logic block IP may be variously changed. In some implementations, each of the first to seventh interlayer insulating layers 110, 120, 130, 140, 150, 160, and 170 may include a silicon oxide layer. The first to seventh interlayer insulating layers 110, 120, 130, 140, 150, 160, and 170 may refer to the front-side interlayer insulating layer FILD of FIG. 4.

A pair of division structures DB may be provided to be opposite to each other in the second direction D2 and may be extended in the first direction D1 and parallel to the gate electrodes GE. A pitch between the division structure DB and the gate electrode GE adjacent thereto may be equal to the first pitch.

The division structure DB may be provided to penetrate the gate capping pattern GP and the gate electrode GE and may be extended into the first substrate 105. The division structure DB may penetrate an upper portion of the first substrate 105.

The active contacts AC may be provided to penetrate the first and second interlayer insulating layers 110 and 120 and may be electrically connected to the first source/drain patterns SD1 and the second source/drain patterns, respectively. Each of the active contacts AC may be provided adjacent to a side of the gate electrode GE. When viewed in a plan view, the active contact AC may be a bar-shaped pattern that is extended in the first direction D1.

The active contact AC may be a self-aligned contact. For example, the active contact AC may be formed by a self-alignment process using the gate capping pattern GP and the gate spacer GS. For example, the active contact AC may cover at least a portion of the side surface of the gate spacer GS. In some implementations, the active contact AC may cover a portion of the top surface of the gate capping pattern GP.

Metal-semiconductor compound layers SC (e.g., silicide layers) may be respectively interposed between the active contact AC and the first source/drain pattern SD1 and between the active contact AC and the second source/drain pattern. The active contact AC may be electrically connected to the first source/drain pattern SD1 through the metal-semiconductor compound layer SC. For example, the metal-semiconductor compound layer SC may be formed of or include at least one of titanium silicide, tantalum silicide, tungsten silicide, nickel silicide, or cobalt silicide.

Gate contacts GC may be provided to penetrate the second interlayer insulating layer 120 and the gate capping pattern GP and may be electrically connected to the gate electrodes GE, respectively. When viewed in a plan view, two gate contacts GC may be disposed on and overlapped with the first PMOSFET region PR1. The gate contact GC may be freely disposed on the gate electrode GE, without any restrictions on its position.

An upper portion of the active contact AC adjacent to the gate contact GC may be filled with an upper insulating pattern UIP. A bottom surface of the upper insulating pattern UIP may be lower than a bottom surface of the gate contact GC. In other words, a top surface of the active contact AC adjacent to the gate contact GC may be formed at a level, which is lower than the bottom surface of the gate contact GC, by the upper insulating pattern UIP. Accordingly, it may be possible to prevent the gate contact GC and the active contact AC, which are adjacent to each other, from being in contact with each other and thereby to prevent a short circuit issue from occurring therebetween. The upper insulating pattern UIP may be formed of or include at least one of silicon-based insulating materials (e.g., silicon oxide, silicon nitride, and silicon oxynitride).

The active contact AC may include a conductive pattern and a barrier metal pattern enclosing the conductive pattern. For example, the conductive pattern may be formed of or include at least one metallic material (e.g., aluminum, copper, tungsten, molybdenum, and cobalt). The barrier metal pattern may cover side and bottom surfaces of a conductive pattern FM. A barrier metal pattern BM may include a metal layer and a metal nitride layer. The metal layer may be formed of or include at least one of titanium, tantalum, tungsten, nickel, cobalt, or platinum. The metal nitride layer may be formed of or include at least one of titanium nitride (TiN), tantalum nitride (TaN), tungsten nitride (WN), nickel nitride (NiN), cobalt nitride (CoN), or platinum nitride (PtN). Similarly, the gate contact GC may include a conductive pattern and a barrier metal pattern enclosing the conductive pattern. The conductive pattern and the barrier metal pattern may include substantially the same material as the conductive pattern and the barrier metal pattern in the active contact AC, respectively.

The power delivery network PDN may be provided on the second surface 105b of the first substrate 105. The power delivery network PDN may include the first to third lower power lines VPR1, VPR2, and VPR3 and the back-side interconnection lines BM1, which are electrically connected to the first to third lower power lines VPR1, VPR2, and VPR3.

The first to third lower power lines VPR1, VPR2, and VPR3 may be extended in the second direction D2 to be parallel to each other. The first lower power line VPR1 may be vertically overlapped with the first NMOSFET region NR1. The second lower power line VPR2 may be vertically overlapped with the first PMOSFET region PR1 and the second PMOSFET region PR2. The third lower power line VPR3 may be vertically overlapped with the second NMOSFET region NR2.

The first to third lower power lines VPR1, VPR2, and VPR3 may be formed of or include at least one selected from the group consisting of copper, molybdenum, tungsten, and ruthenium. A top surface of each of the first to third lower power lines VPR1, VPR2, and VPR3 may be in contact with the second surface 105b of the first substrate 105.

The first and third lower power lines VPR1 and VPR3 may be conduction paths, to which a source voltage (e.g., a ground voltage VSS) is provided. The second lower power line VPR2 may be a conduction path, to which a drain voltage (e.g., a power voltage VDD) is provided.

The back-side contact BC may be provided to penetrate the first substrate 105 and to vertically extend from the second lower power line VPR2 to the first source/drain pattern SD1.

The back-side contact BC may be a conductive pillar-shaped pattern vertically and electrically connecting the second lower power line VPR2 to the first source/drain pattern SD1. The power voltage VDD may be applied to the first source/drain pattern SD1 through the back-side contact BC. The back-side contact BC may be formed of or include at least one metallic material (e.g., tungsten, molybdenum, ruthenium, cobalt, aluminum, and/or copper).

First to third back-side insulating layers 180, 190, and 195 may be sequentially formed on the second surface 105b of the first substrate 105, and the back-side interconnection lines BM1 may be provided in the first to third back-side insulating layers 180, 190, and 195. The first to third back-side insulating layers 180, 190, and 195 may be formed of silicon oxide and may refer to the back-side interlayer insulating layer BILD described with reference to FIG. 4.

In some implementations, the penetration conductive pattern BP may penetrate the first substrate 105 in the third direction D3, at a position horizontally spaced apart from the logic block IP. A vertical length of the penetration conductive pattern BP may be larger than a vertical length of the back-side contact BC. In some implementations, the penetration conductive pattern BP may be provided to penetrate the first and second interlayer insulating layers 110 and 120 and the first back-side insulating layer 180.

The penetration conductive pattern BP may have a circular pillar shape, a tetragonal pillar shape, or a polygonal pillar shape. When measured in a specific direction (e.g., the second direction D2), a width of the penetration conductive pattern BP may be larger than a width of the back-side contact BC. The penetration conductive pattern BP may be formed of or include at least one metallic material (e.g., copper, aluminum, tungsten, molybdenum, and/or cobalt). In addition, the penetration conductive pattern BP may further include a metal nitride layer, which is formed to cover side surfaces thereof. In some implementations, the metal nitride layer may be formed of or include at least one of titanium nitride (TiN), tantalum nitride (TaN), tungsten nitride (WN), nickel nitride (NiN), cobalt nitride (CoN), or platinum nitride (PtN).

The upper conductive patterns FM2 and the upper conductive vias FV2 may be alternately stacked on the top surface of the penetration conductive pattern BP. The lower conductive pattern BM2 and the lower conductive vias BV2 may be sequentially formed on the bottom surface of the penetration conductive pattern BP.

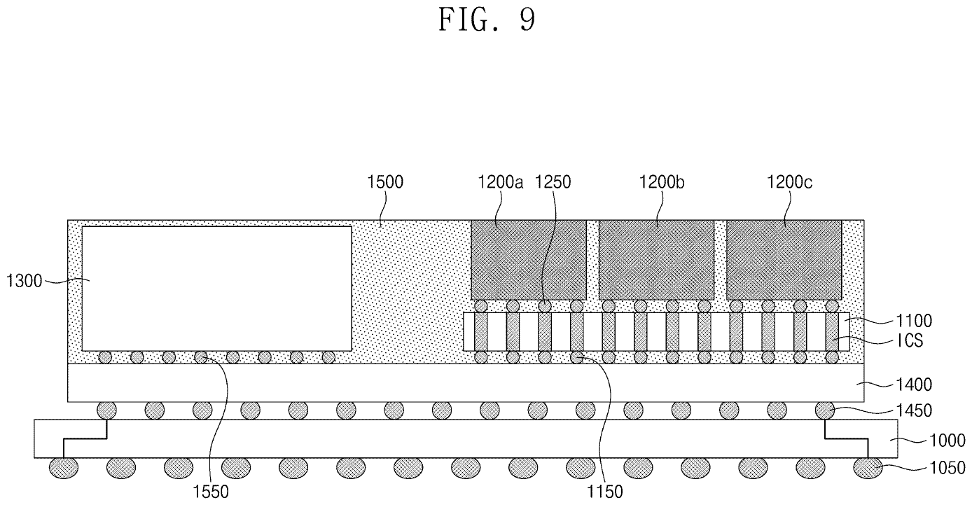

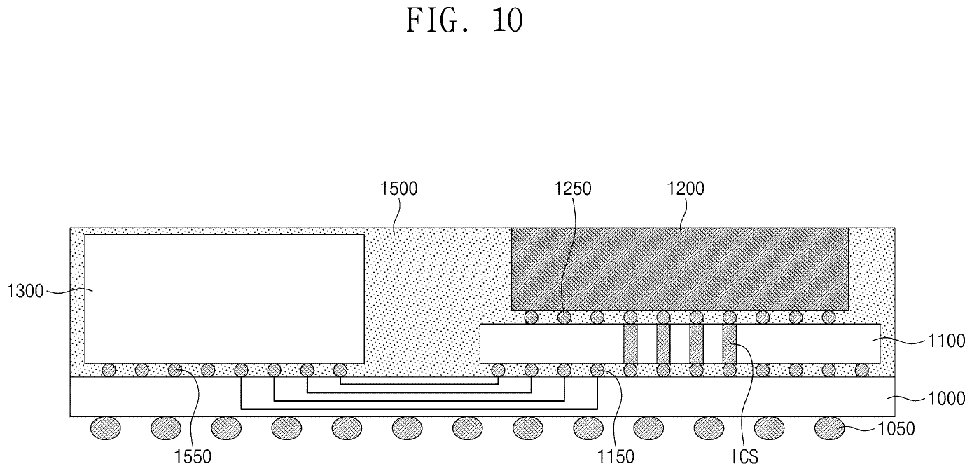

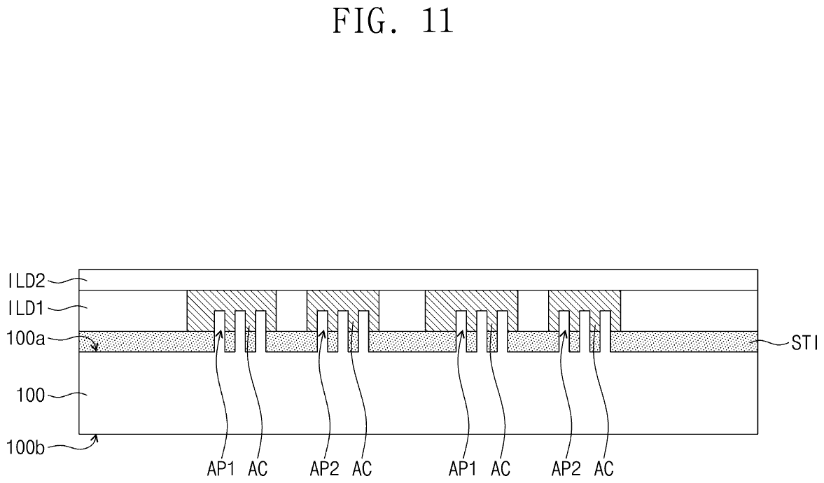

FIGS. 9 and 10 are sectional views illustrating examples of semiconductor packages including a semiconductor device.

Referring to FIG. 9, the semiconductor package may include the base redistribution substrate 1000, an interposer substrate 1400, the first semiconductor device 1100, the second to fourth semiconductor devices 1200a, 1200b, and 1200c, and a fifth semiconductor device 1300. In some implementations, each of the first to fifth semiconductor devices 1100, 1200a, 1200b, 1200c, and 1300 may be a semiconductor chip.

The interposer substrate 1400 may be disposed on the base redistribution substrate 1000, and the first semiconductor device 1100 and the fifth semiconductor device 1300 may be mounted on the interposer substrate 1400. The second to fourth semiconductor devices 1200a, 1200b, and 1200c may be mounted on the first semiconductor device 1100.

In some implementations, the base redistribution substrate 1000, the first semiconductor device 1100, and the second to fourth semiconductor devices 1200a, 1200b, and 1200c may be provided to have substantially the same features as those in the example previously described with reference to FIG. 1. For example, the first semiconductor device 1100 may include the connection structures ICS described above, and the second to fourth semiconductor devices 1200a, 1200b, and 1200c may be electrically connected to the interposer substrate 1400 through the connection structures ICS.

The first connection terminals 1050 may be attached to a bottom surface of the base redistribution substrate 1000, and interposer connection terminals 1450 may be attached to a top surface of the base redistribution substrate 1000. For example, the interposer connection terminals 1450 may be disposed on the interposer substrate 1400 and the base redistribution substrate 1000. The second connection terminals 1150 may be disposed between the interposer substrate 1400 and the first semiconductor device 1100. In addition, the third connection terminals 1250 may be disposed between the first semiconductor device 1100 and the second to fourth semiconductor devices 1200a, 1200b, and 1200c. The interposer connection terminals 1450 and the first, second, and third connection terminals 1050, 1150, and 1250 may be at least one of solder balls, conductive bumps, and conductive pillars. The first, second, and third connection terminals 1050, 1150, and 1250 may be formed of or include at least one of, for example, copper, tin, and lead.

The semiconductor package may exchange signals with another package or external semiconductor devices through the first connection terminals 1050. For example, the semiconductor package may receive a power or ground signal for driving the first to fifth semiconductor devices 1100, 1200a, 1200b, 1200c, and 1300 through at least one of the first connection terminals 1050 of the base redistribution substrate 1000.

The fifth semiconductor device 1300 may be connected to the base redistribution substrate 1000 through the interposer substrate 1400. The interposer substrate 1400 and the base redistribution substrate 1000 may be configured to connect the first semiconductor device 1100 to the fifth semiconductor device 1300 and to provide physical conduction paths, which are formed of conductive materials. Thus, the first semiconductor device 1100 and the fifth semiconductor device 1300 may be mounted on the base redistribution substrate 1000 and may exchange signals with each other.

The fifth semiconductor device 1300 may be disposed on the interposer substrate 1400 to be horizontally spaced apart from the first semiconductor device 1100. The fifth semiconductor device 1300 may include a memory chip. For example, the memory chip may include one of DRAM, SRAM, MRAM, and/or NAND FLASH memory chips.

Fourth connection terminals 1550 may be disposed between the fifth semiconductor device 1300 and the base redistribution substrate 1000. The fifth semiconductor device 1300 may be electrically connected to the interposer substrate 1400 through the fourth connection terminals 1550. The fourth connection terminals 1550 may connect chip pads of the fifth semiconductor device 1300 to the interposer substrate 1400. In addition, the fifth semiconductor device 1300 may be electrically connected to the first semiconductor device 1100 and the second to fourth semiconductor devices 1200a, 1200b, and 1200c through the interposer substrate 1400 or redistribution patterns in the base redistribution substrate 1000.

The semiconductor package may further include a mold layer 1500 covering side surfaces of the first to fifth semiconductor devices 1100, 1200a, 1200b, 1200c, and 1300 and a top surface of the interposer substrate 1400. Although not shown, the mold layer 1500 may cover a top surface of the base redistribution substrate 1000. The mold layer 1500 may be formed of or include, for example, an epoxy mold compound (EMC).

Referring to FIG. 10, a semiconductor package may include the base redistribution substrate 1000, the first semiconductor device 1100, the fifth semiconductor device 1300, and a sixth semiconductor device 1200. The first semiconductor device 1100 and the fifth semiconductor device 1300 may be mounted on the base redistribution substrate 1000, and the sixth semiconductor device 1200 may be mounted on the first semiconductor device 1100.

In some implementations, the base redistribution substrate 1000, the first semiconductor device 1100, and the fifth semiconductor device 1300 may be provided to have substantially the same features as those in the examples described with reference to FIG. 9. For example, referring to FIG. 10, the interposer substrate 1400 of FIG. 9 may be omitted, and the sixth semiconductor device 1200 may be provided in place of the second to fourth semiconductor devices 1200a, 1200b, and 1200c.

The sixth semiconductor device 1200 may execute applications, which are supported by the semiconductor package, and, in some implementations, the first semiconductor device 1100 may be used for the execution of the applications. In some implementations, the sixth semiconductor device 1200 may include at least one processor (e.g., a central processing unit (CPU), an application processor (AP), a graphics processing unit (GPU), a neural processing unit (NPU), a tensor processing unit (TPU), a vision processing unit (VPU), an image signal processor (ISP), and/or a digital signal processor (DSP)) configured to execute operations.

FIGS. 11 to 13E are diagrams illustrating an example of a method of fabricating a semiconductor device.

Referring to FIG. 11, a first semiconductor substrate 100 may be provided. The first semiconductor substrate 100 may be, for example, a silicon substrate. The first semiconductor substrate 100 may have a first surface 100a and a second surface 100b, which are opposite to each other.

First and second active patterns AP1 and AP2 may be formed on the first surface 100a of the first semiconductor substrate 100. The first and second active patterns AP1 and AP2 may be line-shaped patterns, which are extended in a specific direction and parallel to each other. Trenches may be formed by patterning the first semiconductor substrate 100, and the first and second active patterns AP1 and AP2 may be formed, as a result of the formation of the trenches. In some implementations, the first and second active patterns AP1 and AP2 may be portions of the first semiconductor substrate 100 and may be defined by the trenches formed in the first semiconductor substrate 100.

The device isolation layer STI may be formed between the first and second active patterns AP1 and AP2. A top surface of the device isolation layer STI may be formed at a level lower than the top surfaces of the first and second active patterns AP1 and AP2, and thus, upper portions of the first and second active patterns AP1 and AP2 may be exposed.

The gate electrode GE (e.g., of FIG. 8) and the active contacts AC may be formed. The active contacts AC may be in contact with the first and second active patterns AP1 and AP2. Each of the active contacts AC may include a barrier metal layer and a metal layer.

A first interlayer insulating layer ILD1 may be formed on the first substrate 105. The first interlayer insulating layer ILD1 may cover the gate spacers GS (e.g., of FIG. 8), the first source/drain patterns SD1 (e.g., of FIG. 8), and the second source/drain patterns. A second interlayer insulating layer ILD2 may be stacked on the first interlayer insulating layer ILD1.

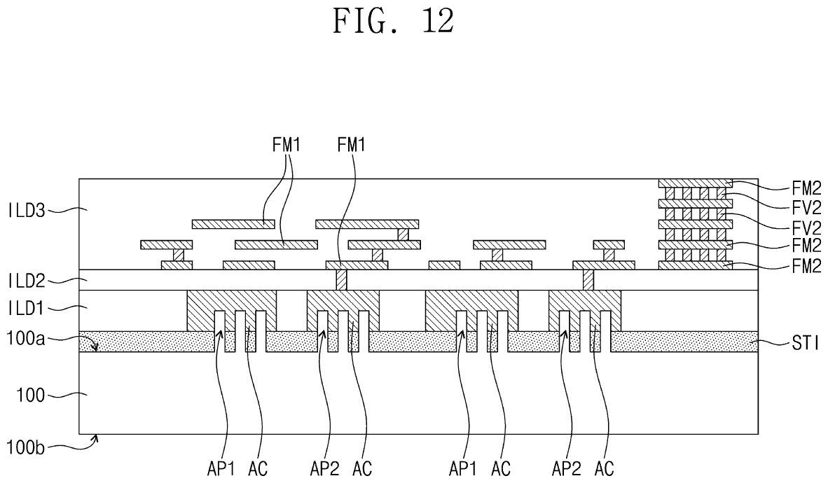

Referring to FIG. 12, the upper interconnection lines FM1 may be stacked on the second interlayer insulating layer ILD2. The upper interconnection lines FM1 may be formed in a third interlayer insulating layer ILD3 including a plurality of insulating layers. The upper interconnection lines FM1, which are vertically stacked, may be electrically connected to each other through contact plugs and may be connected to the logic block (i.e., the gate electrodes and the active contacts). The upper conductive patterns FM2 and the upper conductive vias FV2 may be formed together during the formation of the upper interconnection lines FM1 connected to the logic block. A top surface of the uppermost one of the upper conductive patterns FM2 may be coplanar with a top surface of the third interlayer insulating layer ILD3. The first to third interlayer insulating layers ILD1, ILD2, and ILD3 may be formed of or include, for example, silicon oxide and may refer to the front-side interlayer insulating layer FILD of FIG. 4.

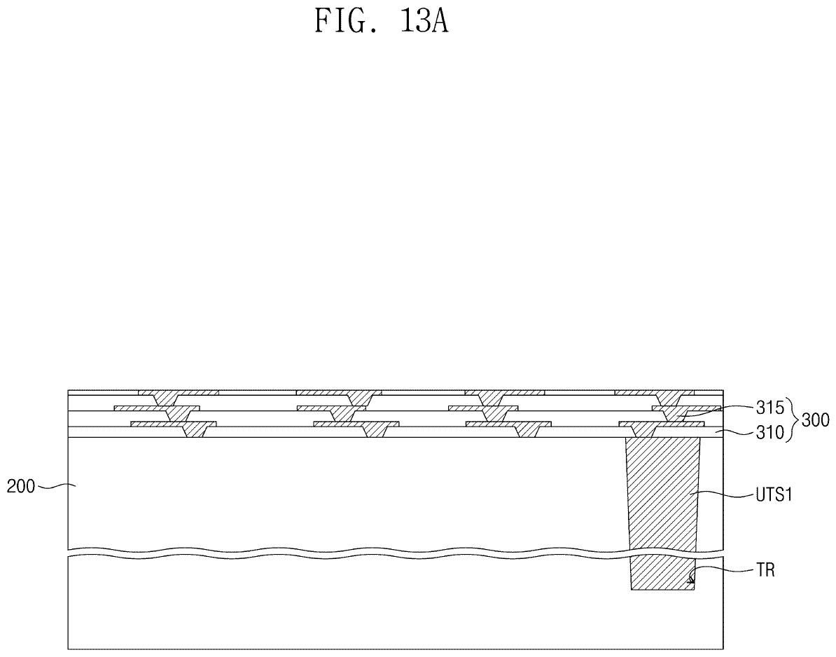

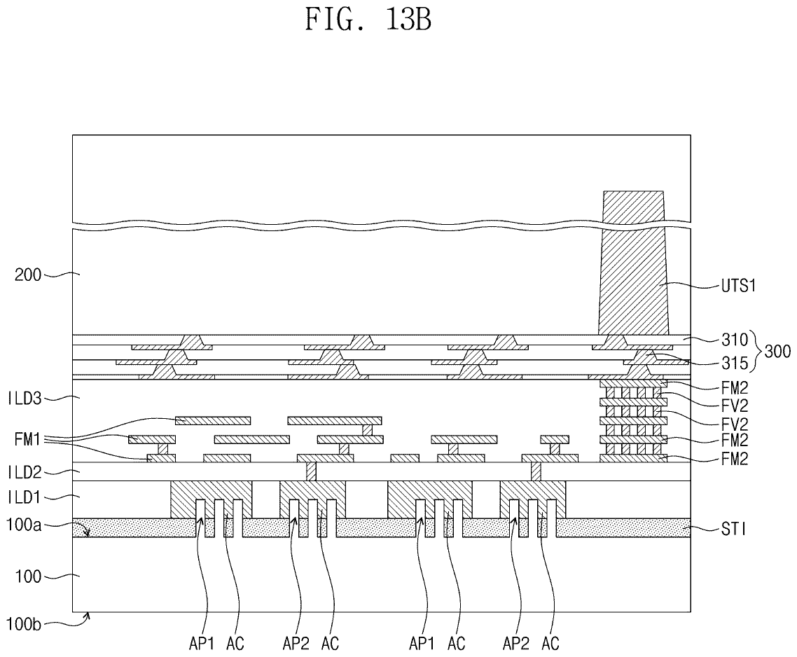

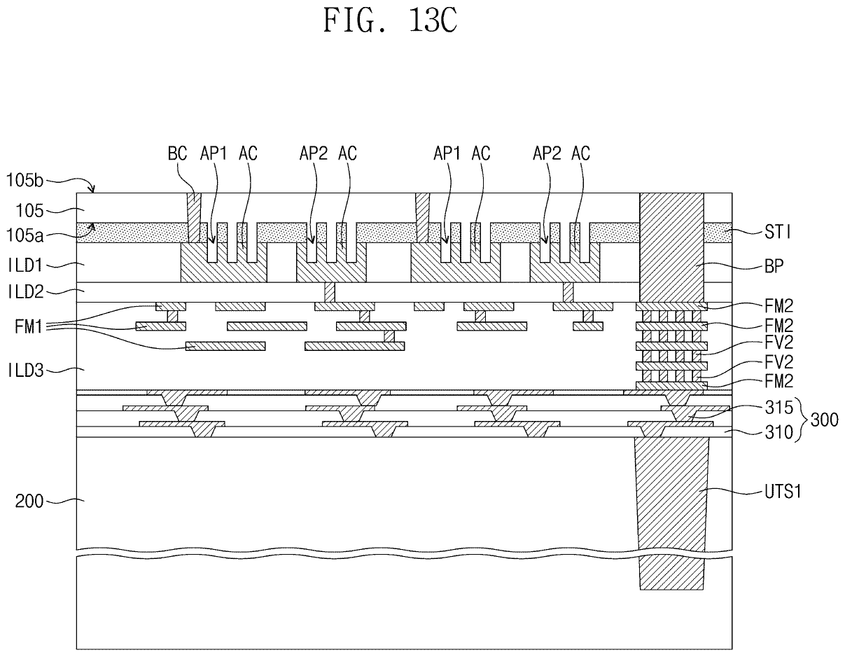

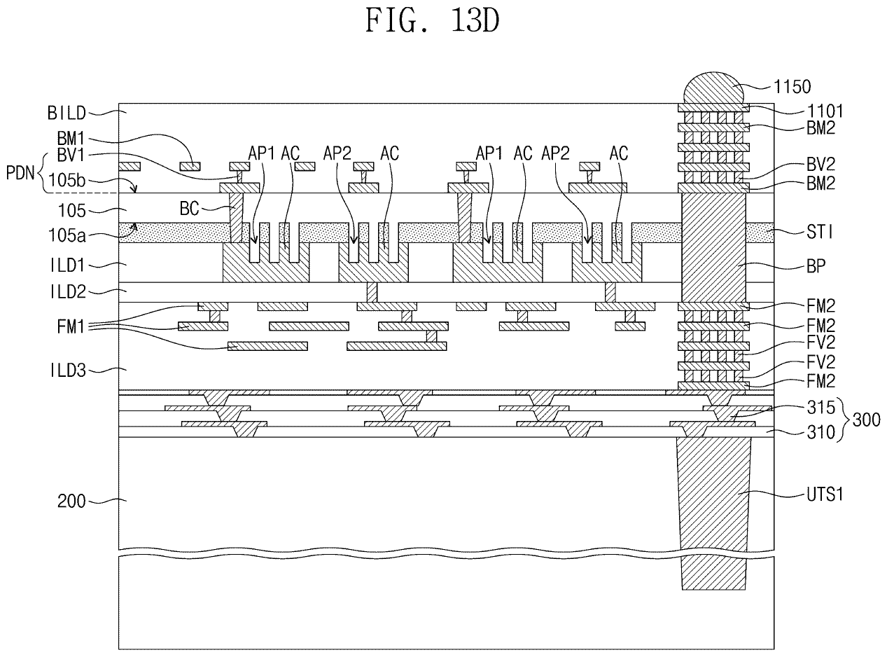

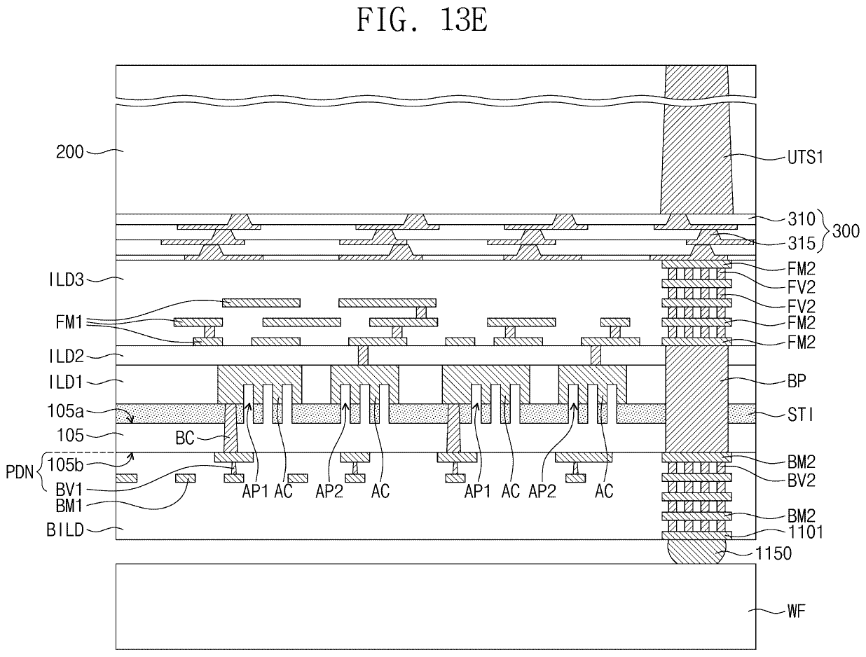

Referring to FIG. 13A, the second substrate 200 may be prepared. The second substrate 200 may include a trench TR, which is formed by patterning a surface of the second substrate 200. The first upper penetration structure UTS1 may be formed in the trench TR of the second substrate 200. In some implementations, the first upper penetration structure UTS1 may be formed by filling the trench TR with a conductive material.

The redistribution substrate 300 (sometimes referred to as a redistribution structure) may be formed on the first upper penetration structure UTS1 and the second substrate 200. The formation of the redistribution substrate 300 may include forming the insulating layer 310 on the second substrate 200 and forming the redistribution pattern 315 to penetrate the insulating layer. The formation of the redistribution pattern 315 may include patterning the insulating layer 310 to form an opening, forming a seed layer in the opening and on a top surface of the insulating layer 310, forming a mask on the seed layer to define a space, in which a conductive pattern will be formed, performing an electroplating process using the seed layer as an electrode to form the conductive pattern, removing the mask, and patterning the seed layer using the conductive pattern as an etch mask. The redistribution patterns 315 may be formed by repeating the process. At least one of the redistribution patterns 315 may be formed to be connected to the first upper penetration structure UTS1.

Referring to FIG. 13B, the redistribution substrate 300 and the second substrate 200 of FIG. 13A may be inverted and then may be placed on the third interlayer insulating layer ILD3. The third interlayer insulating layer ILD3 may be in contact with a surface of the redistribution substrate 300. The redistribution patterns 315 corresponding to the first upper penetration structure UTS1 may be in contact with the uppermost one of the upper conductive patterns FM2.

Referring to FIGS. 13B and 13C, a thinning process may be performed to reduce the thickness of the first semiconductor substrate 100. The thinning process may include grinding or polishing the second surface 100b of the first semiconductor substrate 100 and anisotropically or isotropically etching the ground or polished structure.

For example, the first semiconductor substrate 100 may be inverted, a grinding or polishing process may be performed to remove a portion of the first semiconductor substrate 100, and then, an anisotropic or isotropic etching process may be performed to remove defects, which are present on the surface of the first semiconductor substrate 100.

Next, a replacement process may be performed to replace the first semiconductor substrate 100 with the first substrate 105, which is formed of an insulating material. The first substrate 105 may include the first and second active patterns AP1 and AP2, similar to the first semiconductor substrate 100. In addition, the first substrate 105 may have the first surface 105a, which is in contact with the device isolation layer STI, and the second surface 105b, which is opposite to the first surface 105a.

Thereafter, penetration holes exposing at least one of the active contacts AC or the source/drain patterns may be formed by patterning the second surface 105b of the first substrate 105. The penetration holes may be formed to have a vertical length of about 1 μm or less. Next, the back-side contacts BC may be formed by filling the penetration holes with a metallic material and planarizing the metallic material to expose the second surface 105b of the first substrate 105.

After the formation of the back-side contacts BC, the penetration conductive pattern BP may be formed to penetrate the first substrate 105. The formation of the penetration conductive pattern BP may include patterning the first substrate 105 and the first and second interlayer insulating layers ILD1 and ILD2 through the second surface 105b to form penetration holes exposing the upper conductive patterns FM2, filling the penetration holes with a metallic material, and planarizing the metallic material to expose the second surface 105b of the first substrate 105.

Referring to FIG. 13D, after the formation of the penetration conductive pattern BP, the power delivery network PDN may be formed on the second surface 105b of the first substrate 105. The power delivery network PDN may include the back-side interlayer insulating layers BILD and power lines or the back-side interconnection lines BM1, which are interposed between the back-side interlayer insulating layers BILD. In addition, in the process of forming the back-side interconnection lines BM1, the lower conductive patterns BM2 and the lower conductive vias BV2 may be formed on the penetration conductive pattern BP. The lower chip pad 1101 may be formed on the uppermost one of the lower conductive patterns BM2. The lower chip pad 1101 may be electrically connected to the penetration conductive pattern BP through the lower conductive patterns BM2 and the lower conductive vias BV2.

Next, the second connection terminal 1150 may be attached to the lower chip pad 1101. The lower chip pad 1101 may be formed of or include at least one of copper, nickel, zinc, gold, silver, platinum, palladium, chromium, titanium, or alloys thereof. The second connection terminals 1150 may be formed of or include at least one of tin, silver, lead, nickel, copper, or alloys thereof.

Referring to FIG. 13E, a sub-substrate WF may be formed, and it may be connected to the second connection terminal 1150. The sub-substrate WF may be the base redistribution substrate 1000 of FIG. 1 or the interposer substrate 1400 of FIG. 9, but the scope of the present disclosure is not limited to this example. The sub-substrate WF may be attached to the second connection terminal 1150, and then, the second substrate 200 may be inverted. Thereafter, a grinding process may be performed on the second substrate 200 to expose a top surface of the first upper penetration structure UTS1.

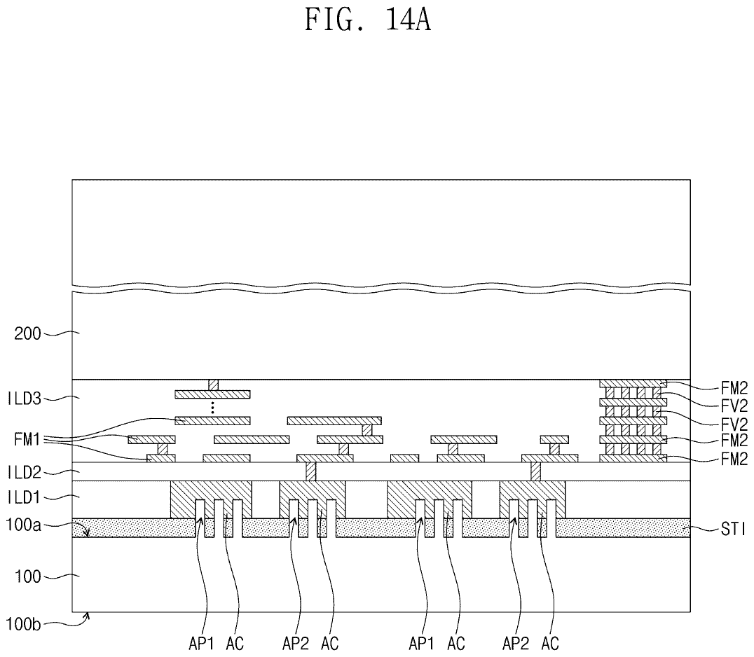

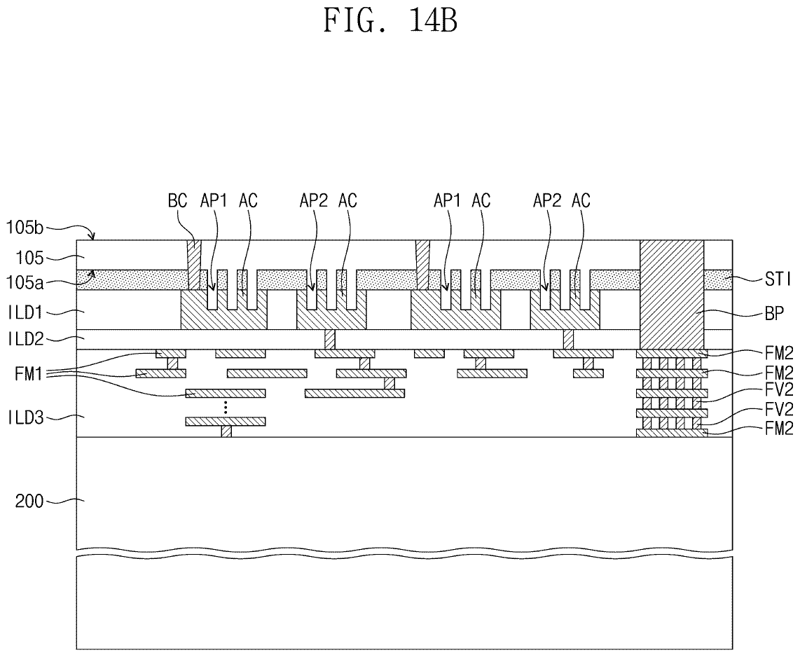

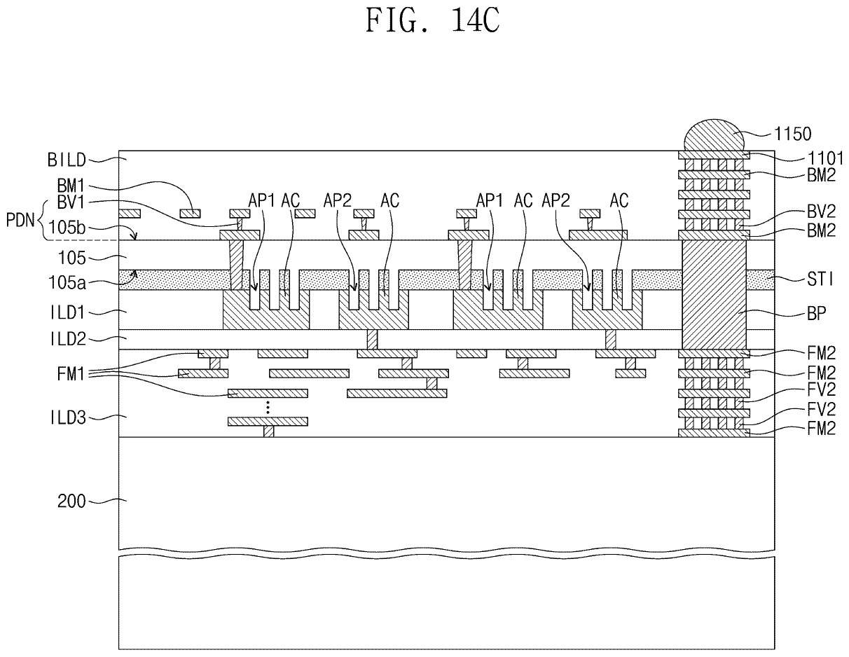

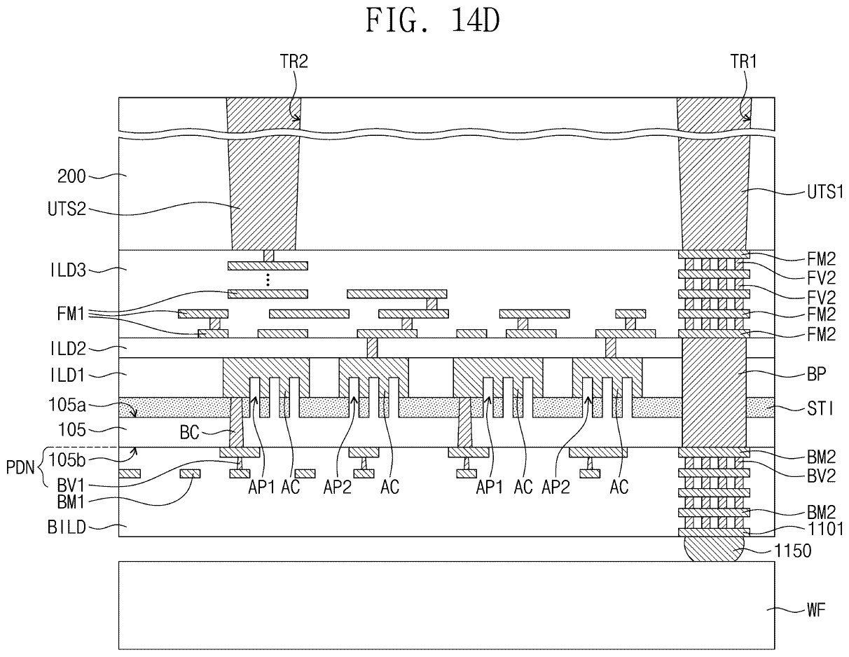

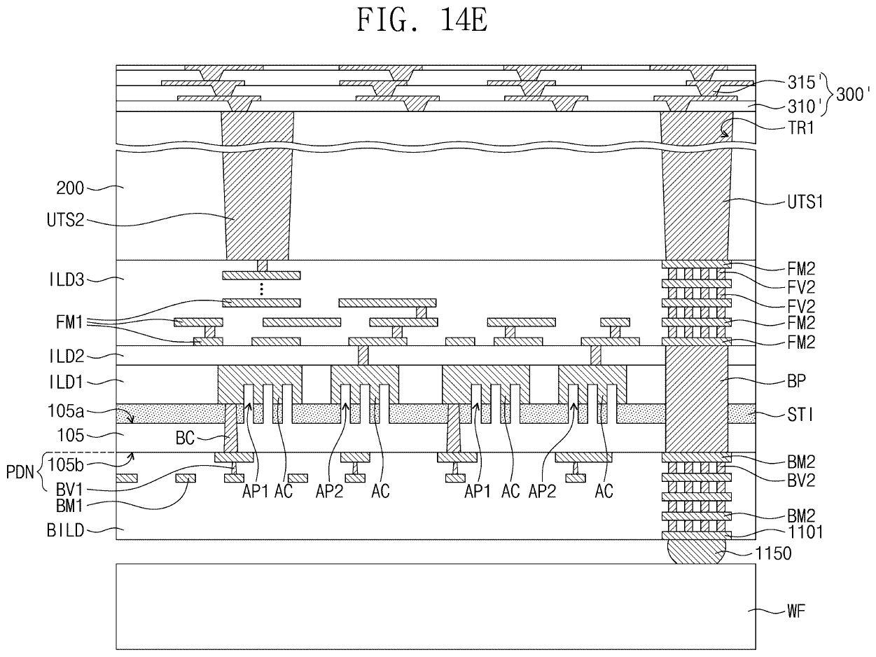

FIGS. 14A to 14E are diagrams illustrating an example of a method of fabricating a semiconductor device, which is different in some ways from the method shown in FIGS. 13A to 13E. The fabrication process of FIGS. 14A to 14E may be performed after the fabrication process described with reference to FIGS. 11 and 12. In the following description, a previously described element may be identified by the same reference number without repeating an overlapping description thereof, for the sake of brevity.

Referring to FIG. 14A, the second substrate 200 may be disposed on the third interlayer insulating layer ILD3. An adhesive layer may be further disposed between the second substrate 200 and the third interlayer insulating layer ILD3.

Referring to FIG. 14B, a thinning process may be performed to reduce the thickness of the first semiconductor substrate 100.

The first semiconductor substrate 100 may be vertically inverted, and a grinding or polishing process may be performed to remove a portion of the first semiconductor substrate 100. Next, a replacement process may be performed to replace the first semiconductor substrate 100 with the first substrate 105, which is formed of an insulating material.

Penetration holes exposing at least one of the active contacts AC or the source/drain patterns may be formed by patterning the second surface 105b of the first substrate 105. The penetration holes may be filled with a metallic material, and then, the back-side contacts BC may be formed by planarizing the metallic material to expose the second surface 105b of the first substrate 105. After the formation of the back-side contacts BC, the penetration conductive pattern BP may be formed to penetrate the first substrate 105.

Referring to FIG. 14C, after the formation of the penetration conductive pattern BP, the power delivery network PDN may be formed on the second surface 105b of the first substrate 105. The power delivery network PDN may include the back-side interlayer insulating layers BILD and the power lines or the back-side interconnection lines BM1, which are interposed between the back-side interlayer insulating layers BILD. In addition, in the process of forming the back-side interconnection lines BM1, the lower conductive patterns BM2 and the lower conductive vias BV2 may be formed on the penetration conductive pattern BP. The lower chip pad 1101 may be formed on the uppermost one of the lower conductive patterns BM2. The second connection terminal 1150 may be attached to the lower chip pad 1101.

Referring to FIG. 14D, the sub-substrate WF may be provided, and it may be connected to the second connection terminal 1150. The sub-substrate WF may be the base redistribution substrate 1000 described with reference to FIG. 1, but the scope of this disclosure is not limited to this example. The sub-substrate WF may be attached to the second connection terminal 1150, and then, the semiconductor package may be vertically inverted.

The second substrate 200 may be patterned to form first and second trenches TR1 and TR2 penetrating the second substrate 200. A metallic material may be formed to fill the first and second trenches TR1 and TR2, and then, the first and second upper penetration structures UTS1 and UTS2 may be formed by planarizing the metallic material to expose a top surface of the second substrate 200. The first upper penetration structure UTS1 may be vertically overlapped with the penetration conductive pattern BP and may be connected to the upper conductive patterns FM2. The second upper penetration structure UTS2 may be connected to the upper interconnection lines FM1.

Referring to FIG. 14E, the redistribution substrate 300′ may be formed on the first and second upper penetration structures UTS1 and UTS2 and the second substrate 200. The formation of the redistribution substrate 300 may include forming the insulating layer 310′ on the second substrate 200 and forming the redistribution pattern 315′ to penetrate the insulating layer.

According to some implementations, a connection structure may be provided to electrically connect top and bottom ends of a first semiconductor chip to each other. The connection structure may include a lower penetration structure, which is provided to penetrate a first substrate with logic blocks, an upper penetration structure, which is provided to penetrate a second substrate on the first substrate, and a redistribution substrate, which is electrically connected to them. The connection structure may serve as an electrical conduction path, which is used to deliver electrical signals and/or power to a semiconductor chip stacked on the first semiconductor chip.

In some implementations, a plurality of semiconductor chips may be disposed on the first semiconductor chip, and thus, a semiconductor package may be provided in a chiplet structure. The semiconductor chips may selectively receive the electrical signals and/or the power from the first semiconductor chip through the redistribution substrate.

Furthermore, heat, which is generated when the first semiconductor chip is operated, may be transferred to the second substrate with high thermal conductivity and may be exhausted to the outside through side surfaces of the second substrate. Thus, the heat-dissipation performance of the first semiconductor chip may be improved, and it may be possible to prevent the performance of the semiconductor chip from being deteriorated.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to examples thereof, it will be apparent to those of ordinary skill in the art that various changes and modifications may be made thereto without departing from the spirit and scope of the present disclosure.

What is claimed is:

1. A semiconductor device comprising:
a first substrate having a first surface and a second surface, wherein the first surface and the second surface face in opposite directions;
a logic block on the first surface of the first substrate;
a power delivery network below the second surface of the first substrate, the power delivery network comprising back-side interconnection lines electrically connected to the logic block;
a second substrate on the logic block;
a redistribution structure between the first substrate and the second substrate;
a first upper penetration structure extending in the second substrate and electrically connected to the redistribution structure; and
a lower penetration structure below the redistribution structure and the first upper penetration structure, wherein the lower penetration structure electrically connects the redistribution structure to a lower chip pad, and wherein the lower chip pad is below the second surface of the first substrate.

2. The semiconductor device of claim 1, wherein the lower penetration structure comprises:
a penetration conductive pattern horizontally spaced apart from the logic block and extending in the first substrate;
upper conductive patterns on a top surface of the penetration conductive pattern and electrically connected to the penetration conductive pattern; and
lower conductive patterns below a bottom surface of the penetration conductive pattern and electrically connected to the penetration conductive pattern.

3. The semiconductor device of claim 2, wherein the upper conductive patterns and the lower conductive patterns are vertically overlapping with the penetration conductive pattern.

4. The semiconductor device of claim 2, comprising:
upper conductive vias between adjacent ones of the upper conductive patterns and electrically connecting the adjacent ones of the upper conductive patterns; and
lower conductive vias between adjacent ones of the lower conductive patterns and electrically connecting the adjacent ones of the lower conductive patterns.

5. The semiconductor device of claim 2, comprising upper interconnection lines, wherein the upper interconnection lines are on the first surface of the first substrate and are electrically connected to the logic block, and
wherein a top surface of a lowermost one of the upper conductive patterns is coplanar with a top surface of at least one of the upper interconnection lines.

6. The semiconductor device of claim 1, comprising a front-side interlayer insulating layer on the first surface of the first substrate and covering the logic block, wherein the front-side interlayer insulating layer is between the redistribution structure and the logic block, and
wherein the lower penetration structure comprises:
a penetration conductive pattern in the front-side interlayer insulating layer and electrically connected to the redistribution structure;
upper interconnection lines electrically connecting the penetration conductive pattern to the logic block; and
lower interconnection lines electrically connecting the logic block to the lower chip pad.

7. The semiconductor device of claim 6, wherein the penetration conductive pattern is vertically spaced apart from the first substrate.

8. The semiconductor device of claim 1, comprising:
a second upper penetration structure, wherein the second upper penetration structure:
is horizontally spaced apart from the first upper penetration structure,
extends in the second substrate, and
is electrically connected to the redistribution structure; and
upper interconnection lines electrically connecting the redistribution structure to the logic block.

9. The semiconductor device of claim 1, wherein a width of the first upper penetration structure increases as a distance to the first surface of the first substrate decreases.

10. The semiconductor device of claim 1, wherein the redistribution structure comprises:
insulating layers below a bottom surface of the second substrate; and
redistribution patterns in the insulating layers,
wherein each of the redistribution patterns comprises:
a line portion that extends parallel to the first surface of the first substrate, and
a via portion that protrudes upward from the line portion,
wherein a width of the via portion increases as a distance to the first surface of the first substrate decreases.

11. The semiconductor device of claim 1, wherein the logic block comprises:
a first source/drain pattern and a second source/drain pattern;
a channel pattern between the first source/drain pattern and the second source/drain pattern, the channel pattern comprising a plurality of semiconductor patterns, wherein the plurality of semiconductor patterns are stacked spaced apart from each other;
a gate electrode on the channel pattern;
an active contact electrically connected to the first source/drain pattern, wherein the active contact is on the first source/drain pattern;
upper interconnection lines electrically connected to the active contact; and
a back-side contact electrically connecting the second source/drain pattern to one of the back-side interconnection lines, wherein the back-side contact is below the second source/drain pattern.

12. A semiconductor device comprising:
a first substrate having a first surface and a second surface, wherein the first surface and the second surface face in opposite directions;
a logic block on the first surface of the first substrate;
a power delivery network below on the second surface of the first substrate, the power delivery network comprising back-side interconnection lines electrically connected to the logic block;
a second substrate on the logic block;
a first upper penetration structure extending in the second substrate;
a second upper penetration structure extending in the second substrate and horizontally spaced apart from the first upper penetration structure;
a lower penetration structure electrically connecting the first upper penetration structure to a lower chip pad, wherein the lower chip pad is below the second surface of the first substrate; and
a redistribution structure electrically connected to the first and second upper penetration structures, wherein the redistribution structure is in contact with the second substrate, and
wherein the second upper penetration structure is electrically connected to the logic block.

13. The semiconductor device of claim 12, wherein the lower penetration structure comprises:
a penetration conductive pattern horizontally spaced apart from the logic block and extending in the first substrate;
upper conductive patterns on a top surface of the penetration conductive pattern; and
lower conductive patterns below a bottom surface of the penetration conductive pattern,
wherein the upper conductive patterns and the lower conductive patterns are vertically overlapping with the penetration conductive pattern.

14. The semiconductor device of claim 12, wherein the lower penetration structure comprises:
a penetration conductive pattern in contact with the first upper penetration structure;
upper interconnection lines electrically connecting the penetration conductive pattern to the logic block; and
lower interconnection lines electrically connecting the logic block to the lower chip pad,
wherein the penetration conductive pattern is vertically spaced apart from the first substrate.

15. The semiconductor device of claim 12, comprising a heat-dissipation pattern between a bottom surface of the second substrate and the first substrate,
wherein the first and second upper penetration structures extend in the heat-dissipation pattern.

16. The semiconductor device of claim 12, wherein a width of each of the first and second upper penetration structures decreases as a distance to the first surface of the first substrate decreases.

17. A semiconductor package comprising:
a base redistribution substrate;
a first semiconductor chip on the base redistribution substrate; and
second and third semiconductor chips on the first semiconductor chip and horizontally spaced apart from each other,
wherein the first semiconductor chip comprises:
a first substrate;
a logic block on a first surface of the first substrate;
upper interconnection lines on the first surface of the first substrate and electrically connected to the logic block;
a power delivery network on a second surface of the first substrate, the power delivery network comprising power lines electrically connected to the logic block;
a second substrate on the logic block, wherein a bottom surface of the second substrate faces the first surface of the first substrate; and
a connection structure extending in the first and second substrates,
wherein the connection structure comprises:
a redistribution structure between the first substrate and the second substrate;
a first upper penetration structure extending in the second substrate and electrically connected to the redistribution structure; and
a lower penetration structure electrically connecting the redistribution structure to a lower chip pad, wherein the lower chip pad is below the second surface of the first substrate.

18. The semiconductor package of claim 17, wherein the lower penetration structure comprises:
a penetration conductive pattern extending in the first substrate and horizontally spaced apart from the logic block;
upper conductive patterns on a top surface of the penetration conductive pattern, above the first surface of the first substrate; and
lower conductive patterns below a bottom surface of the penetration conductive pattern, below the second surface of the first substrate.

19. The semiconductor package of claim 17, wherein the logic block comprises:
a first source/drain pattern and a second source/drain pattern;
a channel pattern between the first source/drain pattern and the second source/drain pattern, wherein the channel pattern comprises a plurality of semiconductor patterns stacked spaced apart from each other;
a gate electrode on the channel pattern;
an active contact electrically connected to the first source/drain pattern, wherein the active contact is on the first source/drain pattern, wherein the upper interconnection lines are electrically connected to the active contact; and
a back-side contact electrically connecting the second source/drain pattern to a back-side interconnection line of the power delivery network, wherein the back-side contact is below the second source/drain pattern.

20. The semiconductor package of claim 17, comprising:
an interposer substrate between the base redistribution substrate and the first semiconductor chip; and
a fourth semiconductor chip on the interposer substrate and horizontally spaced apart from the first semiconductor chip.
